(19) United States
(12) Patent Application Publication
(10) Pub. No.: US 2010/0057381 A1
(43) Pub. Date: Mar. 4, 2010

(54) IMPOSING AND DETERMINING STRESS IN SUB-MICRON SAMPLES

(76) Inventors: Thomas Pardoen, Mont Saint Guibert (BE); Jean-Pierre Raskin, Saint Germain (DE); Pierre Carbonnelle, Woluwe Saint Lambert (BE); Sébastien Gravier, Vizille (FR)

Correspondence Address: BACON & THOMAS, PLLC, 625 SLATERS LANE, FOURTH FLOOR, ALEXANDRIA, VA, 22314-1176, US

(21) Appl. No.: 12/527,035

(22) PCT Filed: Feb. 14, 2008
(86) PCT No.: PCT/EP08/51810

§ 371 Date: Aug. 13, 2009

(30) Foreign Application Priority Data
Feb. 14, 2007 (BE) 2007/000017

(51) Int. Cl. G01L 5/00; H05K 3/30

(52) U.S. Cl. 702/42; 29/832; 977/700

(57) ABSTRACT

This invention provides a method and device for imposing and determining mechanical stress and/or strain, on micro-scale and nano-scale beams, films or multi-layers of materials such as metallic materials, polymer materials, ceramic materials, carbon-based materials and silicon-based materials using a set of micro- or nano-machines. The present invention also provides methods to derive and modify various properties or state of such nano- or microstructures, among others mechanical properties, and to measure the external stimulus that they are subjected to.

### FIELD OF THE INVENTION

The present invention relates to the field of micro- and nano-scale measurement systems and techniques as well as to micro- and nano-fabrication techniques. The present invention particularly relates to methods, devices and systems for imposing and determining mechanical stress and/or strain in nano- or microstructures. Such nano- or microstructures may be for example thin films, thin beams and thin multi-layers. The present invention also relates to methods to derive and modify various properties or state of such nano- or microstructures, among others mechanical properties. The invention has applications in materials production industry, as well as in micro-electronics and for surface treatments and functionalisation.

### BACKGROUND OF THE INVENTION

Materials and structures with micro- or nano-scale dimensions do not behave like conventional macro-scale components. Mechanical properties of sub-micron structures exhibit significant size effects which very much affect the design of the micro and nano systems. For instance, thin films or thin beams such as routinely used in microelectronics and micro-electromechanical systems (the latter being commonly referred to as MEMS) or in thin mono or multilayer coatings may exhibit certain dependence of properties on their dimensions and defect structures having size-dependent deleterious effects on the structural integrity and reliability of said thin films and, consequently, on the reliability of components including them throughout their life expectancy.

Furthermore, materials under mechanical stress often have different electrical, chemical and, in general, physical properties compared to unstressed materials. While this can be observed with bulk material, micro- and nano-structures are expected to exhibit new behaviors. Introducing in a controlled way and determining a mechanical stress or strain in material specimens at micro- and nano-scales is very difficult for a number of reasons: specimens of such size are easily damaged through handling, it is difficult to position specimens of such size to ensure uniform loading along specimen axes, specimens are difficult to attach to the instrument grips, there often is inadequate load resolution, and the data reduction formulas are hypersensitive to precise dimensional measurements.

There is a need for reliable and cost-effective methods and devices for imposing and determining the stress and/or strain applied to thin films, thin beams or thin multi-layers, i.e. structures involving at least one micro- or nano-scale dimension, and for determining the evolution of the stress and/or strain under continuous loading. Mechanical properties of interest for micro- and nano-scale materials (such as metallic materials, polymeric materials, ceramic materials among which oxides or nitrides for instance, carbon-based materials such as carbon nanotubes, and silicon and other semiconductor based materials, and biological materials) include, but are not limited to, Young's modulus, yield strength, tensile strength, fracture strength and fracture toughness. Other properties of interest include coupled chemical properties such as the kinetics and magnitude of absorption and adsorption of chemical elements by materials under mechanical stress, or stress controlled electrical properties such as electron mobility in conductors, piezo-resistivity, piezoelectricity, etc. Such methods and devices would help perform quality control during manufacturing, or gain better knowledge of materials in view of designing better devices, or design new industrial processes that use the new properties of material under stress, which can hence lead to sensor type application. There is still a need in the art for improving the existing methods for imposing and determining mechanical load on small material samples, i.e. material samples having at least one dimension smaller than 10 μm such as thin films, thin beams and thin multilayers, in the presence or in the absence of stimulus additional to the stress imposed. Example of stimulus are chemical, optical, thermal, electrical, optical, chemical, acoustical, or nuclear stimulus or other physical changes. There is a need especially to make these methods more versatile, precise, reliable, simple and cost-effective as well as more robust in the data reduction procedures.

### SUMMARY OF THE INVENTION

It is an object of the present invention to provide good methods and systems for imposing and determining stress and/or strain inside micro- and/or nano-sized materials. It is an advantage of embodiments according to the present invention that reliable methods and systems for imposing and determining the stress and/or strain in micro- and/or nano-sized materials are obtained. It is an advantage of embodiments according to the present invention that simple and/or cost-effective methods and systems for determining mechanical properties of micro- and/or nano-sized materials are obtained. It is an advantage of embodiments according to the present invention that precise and/or accurate methods and systems for determining or modifying physical/material properties of micro- and/or nano-sized materials under mechanical stress are obtained. The present invention also relates in an embodiment to sensors for chemical, optical, thermal, electrical, optical, chemical, acoustical, or nuclear stimulus. Some sensors according to embodiments of the present invention are simple, cost-effective, reliable, precise and/or accurate sensors.

Some embodiments of the present invention surprisingly can advantageously make use of a change in the approach of the mechanical testing of micrometer and nanometer scale films, beams, multilayers and volume elements, by using the potential of micro or nano-fabrication techniques.

The present invention relates to a system for imposing and determining the stress and/or strain imposed to at least one sample nano- or micro-structures, the system comprising

a device comprising a substrate and one or more reference nano- or microstructures directly or indirectly attachable to one or more sample nano- or microstructures to form one or more test nano- or microstructures, wherein said one or more reference nano- or microstructure is directly or indirectly attached to said substrate in such a way that a part of said one or more reference nano- or microstructure can stand free, and
means for directly or indirectly imposing an external mechanical load on said one or more test nano- or microstructures or on said substrate in such a way that the stress and/or strain in said reference nano- or microstructure is essentially uniformly compressive or tensile.

The at least one sample nano- or micro-structure may be one sample nano- or micro-structure or a plurality of sample nano- or micro-structures. The external mechanical load may be a mechanical load that is externally imposed, i.e. induced using an external source. The external mechanical load to a plurality of sample nano- or micro-structures simultaneously.

The one or more reference nano- or micro-structures may have a known mechanical stiffness. Alternatively the mechanical stiffness of the one or more reference nano- or micro-structures may be derivable, e.g. during a calibration procedure. It may be derived from comparison with a calibration material provided as nano- or microstructure.

The imposed external mechanical load may be of unknown intensity.

The imposed external mechanical load applied to the test nano- or microstructure may be such that the imposed external mechanical load applied to the sample nano- or microstructures is a chosen fraction of the stress applied to said reference nano- or microstructure and/or to said substrate from said means for imposing an external mechanical load.

It is an advantage of embodiments according to the present invention that one does not need to know the external force that is applied. It is an advantage of embodiments according to the present invention that there is a possibility to amplify the strain from the means for imposing an external mechanical load, e.g. via the ratio of the stiffness of the materials used. It is an advantage of embodiments according to the present invention that there is a possibility to divide the loading applied to the substrate. It is an advantage of embodiments according to the present invention that there is a possibility to impose and or determine strain and stress to many devices simultaneously.

It is an advantage of embodiments according to the present invention that methods and systems can be provided wherein the measurement can be externally controlled, e.g. the applied force can be controlled by the user. It is an advantage of embodiments according to the present invention that methods and systems are provided that can be used for characterizing sample nano- or micro-structures in a wide range of materials. It is an advantage of embodiments according to the present invention that by linking the sample structure to the one or more reference structure allows the one or more reference to fulfil the purpose of serving as means for deriving a change in length and serving as means for coupling the external stress to the sample structure.

The system furthermore may comprise a means for directly or indirectly providing dimensional and/or strain information on said sample and/or reference and/or test nano- or microstructure based on a response to said imposed external mechanical load on said test nano- or microstructure.

The means for imposing an external mechanical load may reversibly impose said external mechanical load on said test nano- or microstructure. It is an advantage of embodiments according to the present invention that methods and systems can be provided for performing fatigue tests.

The means for imposing an external mechanical load on said test nano- or microstructures may be magnetic, mechanic, electrostatic, electromagnetic, optical, acoustic, thermal, chemical, structural, nuclear or quantum means, or a combination thereof. It is an advantage of embodiments according to the present invention that means for imposing external mechanical load, e.g. stress, can be used that are independent of the material to be mechanically loaded, i.e. that put stringent requirements on the material to be mechanically loaded. It is an advantage of embodiments according to the present invention that multi-physics properties can be studied.

The length of the reference nano- or microstructure may be between twice and one hundred times the length of the sample nano- or microstructure. It is an advantage of embodiments of the present invention that measurement results can be obtained with a good accuracy.

The substrate may comprise a mesh structure. It is an advantage of embodiments according to the present invention that, when using a mesh, an external force/displacement can be easily applied and that high levels of strain in the substrate can be obtained.

The reference nano- or microstructures and/or said sample nano- or microstructures may comprise internal stress. It is an advantage of embodiments according to the present invention that these can take into account internal stress induced by the specific deposition procedure or a temperature mismatch, thus resulting in a higher accuracy of the determined physical properties.

The system may comprise one or more means to apply one or more stimulus on the sample nano- or microstructure and/or to measure one or more states or properties of the sample nano- or microstructure selected from the list consisting of mechanical, electrical, optical, chemical, acoustical, thermal, structural, nuclear and quantum mechanical stimulus, state and/or properties It is an advantage of embodiments according to the present invention that versatile system can be obtained, allowing to provide also information regarding a plurality of physical properties of materials.

The means for directly or indirectly providing dimensional and/or strain information may comprise one or more free sample nano- or microstructures separate from any reference nano- or microstructures, and/or one or more free reference nano- or microstructures separate from any sample nano- or microstructures and/or one or more double clamped beam. It is an advantage of embodiments according to the present invention that accurate variation of the lengths in the sample nano- or microstructures can be derived.

The means for imposing an external mechanical load on said test nano- or microstructure may comprise one or more electrostatic micro-machines.

The means for directly or indirectly providing dimensional and/or strain information may comprise cursors. Such cursors may be used for indicating or deriving a position. It is an advantage of embodiments according to the present invention that the cursors may comprise periodical structures. It is an advantage of embodiments according to the present invention that cursors and optionally periodical structures assist in improvement of the accuracy of the obtained dimensional information.

The means for directly or indirectly providing dimensional and/or strain information may comprise piezo resistive elements. It is an advantage of embodiments according to the present invention that the means for providing dimensional information may permit easier automation of the testing procedure.

The means for directly or indirectly providing dimensional and/or strain information may comprise at least two electrodes, one moving with the test nano- or microstructures and the other one fixed directly or indirectly to a free nano- or microstructure or to the substrate. It is an advantage of embodiments according to embodiments of the present invention that these allow capacitive determination of the dimensional variation and thus an easier automation of the testing procedure.

The sample nano- or microstructures may comprise a section reduction and/or one or more notches and/or one or more holes and/or one or more cracks. It is an advantage of embodiments according to the present invention that reduction of sections allows reduction or avoiding of perturbation effects at the sample end. It is an advantage of embodiments according to the present invention that provision of notches, holes or cracks allows testing in non-homogeneous conditions.

The device may comprise at least two reference nano- or microstructures attached to a sample nano- or microstructure and arranged to test said sample nano- or microstructure in traction, shear, compression, crack propagation or biaxial traction measurement. It is an advantage of embodiments according to the present invention that the system is versatile, allowing to measure different types of stress or strain.

The substrate may comprise a sacrificial portion or layer and the nano- or microstructures can be made free upon removal of the sacrificial portion or layer. It is an advantage of embodiments according to the present invention that prior to use, the system is solid and less subject to damage.

The system furthermore may comprise a processor for deriving one or more physical state or properties of said one or more sample nano- or microstructures from said dimensional and/or strain information and/or from the measurement of state and/or properties of the one or more sample nano- or microstructures selected from the list consisting of mechanical, electrical, optical, chemical, acoustical, thermal, structural, nuclear and quantum mechanical state and properties.

The system may further comprise a controller for adapting said external imposed mechanical load on the one or more test nano- or microstructure as a function of said dimensional and/or strain information and/or of the measurement of state and/or properties of the one or more sample nano- or microstructures selected from the list consisting of mechanical, electrical, optical, chemical, acoustical, thermal, structural, nuclear and quantum mechanical state and properties.

The present invention also relates to a method for assisting in characterization of one or more sample nano- or micro-structures, the method comprising

directly or indirectly imposing an external mechanical load on one or more test nano- or microstructure comprising one or more reference nano- or microstructure directly or indirectly attached to one or more sample nano- or microstructure, wherein the one or more reference nano- or microstructures is directly or indirectly attached to a substrate so as to stand free with respect to the substrate, said external mechanical load being imposed in such a way that induced stress and/or strain in the one or more reference nano- or microstructure is essentially uniformly compressive or tensile.

The method may comprise directly or indirectly providing dimensional and/or strain information on the one or more sample and/or reference and/or test nano- or microstructure based on a response to said imposed external mechanical load on the one or more test nano- or microstructure.

The method furthermore may comprise applying one or more chemical, optical, thermal, electrical, chemical, acoustical, structural, nuclear or quantum mechanical stimulus on the sample nano- and microstructure, and/or determining one or more chemical, optical, thermal, electrical, chemical, acoustical, structural, nuclear or quantum mechanical state or property on the one or more sample nano- or microstructures.

The method furthermore may comprise deriving one or more physical or multi-physics property from said dimensional and/or stress information and/or from the one or more chemical, optical, thermal electrical, chemical, acoustical, structural, nuclear or quantum mechanical state or property measured on the one or more sample nano- or microstructure. The derived physical property may for example be the strain in the structures or physical properties derived therefrom. The method optionally may comprise deriving one or more physical properties in relation with said strain.

The method further may comprise, prior to said imposing an external mechanical load, removing a sacrificial layer on the substrate and/or sacrificial portion of the substrate wherein said one or more sample and/or reference nano- or microstructures are positioned so as to obtain one or more free-standing sample and/or reference nano- or microstructures.

The method furthermore may comprise controlling said stress and/or strain imposed on said test nano- or microstructure as a function of said dimensional and/or strain information and/or of said measurement of state and/or properties of the sample nano- or microstructures selected from the list consisting of mechanical, electrical, optical, chemical, acoustical, thermal, structural, nuclear and quantum mechanical state and properties.

The present invention also relates to a method for manufacturing a system for imposing and determining stress and/or strain to sample nano- or microstructures, the method for manufacturing comprising

forming a device by obtaining a substrate and attaching directly or indirectly one or more reference nano- or microstructures to said substrate so that a part of said one or more reference nano- or microstructure can stand free, said one or more reference nano- or microstructures being directly or indirectly attachable to said one or more sample nano- or microstructure to form one or more test nano- or microstructure, and

providing one or more means for directly or indirectly imposing an external mechanical load on said one or more test nano- or microstructure in such a way that the stress and/or strain induced in the one or more reference nano- or microstructure is essentially uniformly compressive or tensile.

The method may comprise providing the one or more sample nano- or microstructure so that a part of said one or more sample nano- or microstructure can stand free.

The method may comprise providing means for directly or indirectly providing dimensional and/or strain information on said one or more sample and/or reference and/or test nano- or microstructure based on a response to said imposed external mechanical load on said one or more test nano- or microstructure.

The method for manufacturing may optionally comprise providing means for applying one or more chemical, optical, thermal, electrical, optical, chemical, acoustical, or nuclear stimulus on the sample nano- and microstructure. The method for manufacturing may optionally comprise providing means for determining one or more chemical, optical, thermal, electrical, acoustical, or nuclear effects derived from the interaction between the sample nano- and microstructures and the optional stimulus. The method for manufacturing may optionally comprise providing a controller for adapting the stress imposed to the device in function of the dimensional information gained from the means for providing dimensional information on said sample and reference nano- or microstructure.

The present invention also relates to a device for characterizing one or more sample nano- or micro-structures, the device comprising

a substrate comprising a sacrificial portion or layer, and

one or more reference nano- or microstructures directly or indirectly attachable to one or more sample nano- or microstructures to form one or more test nano- or microstructures, wherein the one or more reference nano- or microstructures are attached to said substrate in such a way that a part of said one or more reference nano- or microstructure stands free or would stand free if said optional sacrificial portion or layer was removed, e.g. from below said parts,

said one or more test nano- or microstructures being adapted for being subjected to an external mechanical load directly or indirectly imposed in such a way that the resulting stress and/or strain in the one or more reference nano-microstructure is essentially uniformly compressive or tensile.

The present invention also relates to a method for determining stress and/or strain applied to one or more sample nano- or microstructure comprising the steps of

obtaining a device comprising a substrate and one or more reference nano- or microstructure directly or indirectly attachable to one or more sample nano- or microstructure to form one or more test nano- or microstructure, the one or more reference nano- or microstructure being directly or indirectly attached to the substrate in such a way that a part of the one or more reference nano- or microstructure can stand free with respect to the substrate
obtaining Young modulus related information of the one or more reference nano- or microstructure
subjecting the device to an external mechanical toad in such a way that the stress and/or strain in the reference nano- or microstructure is essentially uniformly compressive or tensile,
deriving dimensional and/or stress information of said sample and/or reference and/or test nano- or micro-structure, and
deriving from said dimensional and/or stress information and said Young modulus related information the stress and/or strain applied to said one or more sample nano- or microstructure.

The present invention also relates to a method for determining the intensity of a chemical, thermal, electrical, optical, acoustical, or nuclear stimulus on one or more sample nano- and microstructures comprising the steps of:

obtaining a device comprising a substrate and one or more reference nano- or microstructure directly or indirectly attachable to one or more sample nano- or microstructures to form one or more test nano- or microstructure, the one or more reference nano- or microstructure being directly or indirectly attached to the substrate so that part of the one or more reference nano- or microstructure can stand free with respect to the substrate
obtaining information regarding the dependency of stress or strain to said stimulus,
imposing an external mechanical load,
subjecting said sample to one or more chemical, optical, thermal, electrical, optical, chemical, acoustical, or nuclear stimulus,
directly or indirectly deriving dimensional and/or stress information from said means for providing dimensional and/or stress information from said sample and/or reference and/or test nano- and microstructure, and
deriving from said dimensional information, said imposed stress and/or strain and said information regarding the dependency of stress or strain to said stimulus, the intensity of said stimulus on said one or more sample nano- and microstructure.

The present invention furthermore relates to a sensor for determining the intensity of a chemical, thermal, electrical, optical, acoustical, or nuclear stimulus on a sample nano- and microstructure, the sensor comprising

a system as described above for imposing and determining the stress and/or strain imposed to at least one sample nano- or micro-structures,

a means for obtaining information regarding the dependency of stress or strain to said stimulus,

a means for subjecting said sample to one or more chemical, optical, thermal, electrical, optical, chemical, acoustical, or nuclear stimulus,

a means for directly or indirectly deriving dimensional and/or stress information from said means for providing dimensional and/or stress information from said sample and/or reference and/or test nano- and microstructure, and for deriving from said dimensional information, said imposed stress and/or strain and said information regarding the dependency of stress or strain to said stimulus, the intensity of said stimulus on said one or more sample nano- and microstructure.

The present invention presents also in some embodiments one or more of the following advantages:

It may provide the possibility to change the mechanical loading conditions easily by changing the stress being imposed to the system.

It may provide the possibility to conduct a full stress-strain test on the same sample, e.g. on the same metallic film or nanotube. The placing of many test structures, which is very difficult/costly, is therefore not necessary.

Repeating the testing on structures of varying dimensions is not necessary which has the advantage of having lower surface requirements on the substrate (e.g. wafer), hence lower cost.

The external load does not have to be known, and can be large.

Particular and preferred aspects of the invention are set out in the accompanying independent and dependent claims. Features from the dependent claims may be combined with features of the independent claims and with features of other dependent claims as appropriate and not merely as explicitly set out in the claims.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1A is a schematic representation of different steps (a), (b) and (c) of an exemplary method for imposing and determining stress and/or strain applied to a test sample according to an embodiment of the present invention.

FIG. 1B is a schematic representation of different steps (a), (b) and (c) of an exemplary method for imposing and determining stress and/or strain applied to a test sample according to another embodiment of the present invention.

FIGS. 2 (a) and (b) represent schematic views of a micro- or nano-structure according to embodiments of the present invention.

FIG. 3 schematically represents a top-view of a micro- or nano-structure on a substrate according to an embodiment of the present invention.

FIG. 4 schematically represents a top-view of a micro- or nano-structure on a substrate according to an embodiment of the present invention.

FIG. 5A (a) and (b) schematically represents a top-view of an assembly substrate-reference nano- or microstructure before and after loading according to an embodiment of the present invention.

FIG. 5B (a) and (b) schematically represents a top-view of a device before and after loading according to an embodiment of the present invention.

FIG. 6A (a) and (b) schematically represents a top-view of an assembly substrate-reference nano- or microstructure before and after loading according to another embodiment of the present invention.

FIG. 6B (a) and (b) schematically represents a top-view of a device before and after loading according to an embodiment of the present invention.

FIGS. 7 (a) and (b) schematically represent a top-view of a test nano- or microstructure before and after loading according to an embodiment of the present invention.

FIGS. 8 (a) and (b) schematically represent a top-view of a test nano- or microstructure before and after loading according to another embodiment of the present invention.

FIGS. 8 (c) and (d) schematically represent a top-view of a test nano- or microstructure before and after loading according to an embodiment of the present invention.

FIG. 9 schematically represents a top-view of a test nano- or microstructure according to an embodiment of the present invention.

FIG. 10 schematically represents a top-view of a test nano- or microstructure according to an embodiment of the present invention.

FIG. 11 schematically represents a top-view of a test nano- or microstructure according to an embodiment of the present invention.

FIG. 12 schematically represents a top-view of a test nano- or microstructure according to an embodiment of the present invention.

FIG. 13 is a photograph showing a test- nano- or microstructure according to an embodiment of the present invention.

FIG. 14 is a photograph showing a test- nano- or microstructure according to an embodiment of the present invention.

FIG. 15 is a photograph showing a test- nano- or microstructure according to an embodiment of the present invention.

FIG. 16 is a photograph showing a test- nano- or microstructure according to an embodiment of the present invention.

FIG. 17 schematically shows an upper view of a system according to an embodiment of the present invention.

FIG. 18 schematically shows an upper view of a system according to another embodiment of the present invention.

FIG. 19 schematically shows an upper view of a substrate with a truss lattice type structure in order to allow imposing large strains without fracture of the substrate, according to an embodiment of the present invention.

FIG. 20 shows an electrostatic micromachine used as a means for applying an external mechanical load to the sample according to an embodiment of the present invention.

In the different figures, the same reference signs refer to the same or analogous elements.

### DETAILED DESCRIPTION OF THE INVENTION

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Similarly, it is to be noticed that the term “coupled” or “connected” or “attached”, also used in the claims, should not be interpreted as being restricted to direct connections only. “Coupled” or “connected” or “attached” may mean that two or more elements are either in direct physical or electrical contact, or that two or more elements are not in direct contact with each other but yet still co-operate or interact with each other.

Similarly, it is to be noticed that the term “or”, also used in the claims, should not be interpreted as “exclusive or”.

Reference throughout this specification to “one embodiment” or “an embodiment” means that a particular feature, structure or characteristic described in connection with the embodiment is included in at least one embodiment of the present invention. Similarly it should be appreciated that in the description of exemplary embodiments of the invention, various features of the invention are sometimes grouped together in a single embodiment, figure, or description thereof but that this is not to be interpreted as reflecting an intention that the claimed invention requires more features than are expressly recited in each claim. Rather, as the following claims reflect, inventive aspects lie in less than all features of a single foregoing disclosed embodiment. Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

The following terms are provided solely to aid in the understanding of the invention. As used herein, and unless stated otherwise, the terms “material to be stressed” or “material sample” refer to any material in which one would like to induce a mechanical stress and/or strain for the purpose (1) of characterizing the mechanical response and/or (2) of modifying and characterizing the change of mechanical state or properties when the sample is subjected to other chemical or physical changes (stimulus such as temperature, sound, electrical field, magnetic field, presence of a chemical substance, nuclear reaction, light, etc.) and/or (3) of characterizing the change of a material or structural state or property under stress such as changed electron mobility, absorption capacity of chemical species, rate of nuclear reaction, damping property, phase transformation, dielectric property, piezoresistive coefficient, etc. Examples of material to be stressed includes, but are not limited to metals, silicon and other semiconductor materials, ceramics, polymers, biological materials, and multilayers made of several layers of the aforementioned materials among others.

As used herein, and unless stated otherwise, the term “reference material” refers to a material whose Young's modulus E_{ref} is known. Examples of reference materials include but are not limited to Polysilicon, Fe, Cu, Si₃N₄, WC, Al₂O₃, AlN, SiC, W, B₄C, Ti, diamond, etc. The first factor of merit may be given by the constancy of the Young's modulus with respect to changes in the fabrication method. Advantageously, single phase materials with low elastic anisotropy may be used. The second factor of merit may be a large yield stress (or, and, it is similar, a large hardness) for the reference material to remain elastic. The third factor of merit may be a good etching selectivity with respect to many chemical agents. A fourth factor of merit may be that the Young's modulus of the reference material is not affected or is affected in a known way by the chemical or physical effects (i.e. the stimulus) imposed to the test material on top of the mechanical load, in other words, the dependency of the Young modulus (and therefore of the stress or strain) to said stimulus is known. It should be noted that in some embodiment of the invention, the reference material can be of the same nature and composition as the material to be stressed.

As used herein, and unless stated otherwise, the term “sample nano- or microstructure”, or simply “sample structure”, refers to a solid object made of the material to be stressed, at least one dimension of which is in the micro- or nanometer range. The at least one dimension may for example have a thickness in the range 10 μm down to 1 nm. A typical sample nano- or microstructure is a beam. The term “reference nano- or microstructure”, or simply “reference structure”, refers to a solid object having the same dimensional limits as set out above but made of reference material and, more generally, whose stiffness is known. As used herein, and unless stated otherwise, the term “test nano- or microstructure”, or simply “test structure” refers to the combination of a sample nano- or microstructure and a reference nano- or microstructure connected together. As used herein, and unless stated otherwise, the term “connection point” or “connection region” refers to the point or region where the sample nano- or microstructure and the reference nano- or microstructure are connected in a test nano- or microstructure.

As used herein, and unless stated otherwise, the term “actuation point” or “actuation region” refers to the point or region where a nano- or microstructure (e.g. sample or reference) is or can be directly or indirectly connected to the substrate, to the sacrificial layer or to the means to apply an external mechanical load.

As used herein, and unless stated otherwise, the term “free sample nano- or microstructure”, or simply “free sample structure”, refers to a sample nano- or microstructure that is not connected to a reference nano- or microstructure. The term “free reference nano- or microstructure”, or simply “free reference structure”, refers to a reference nano- or microstructure that is not connected to a sample nano- or microstructure. The term “end point of the free sample nano- or microstructure” or “end region of the free sample nano- or microstructure” refers to the point or region where the sample nano- or microstructure would meet the reference nano- or microstructure if they were connected. The term “end point of the free reference nano- or microstructure” or “end region of the free reference nano- or microstructure” refers to the point or region where the reference nano- or microstructure would meet the sample nano- or microstructure if they were connected.

The term “double clamped beam” refers to a beam that is connected on both ends to the substrate; it can be of the same or different material as the sample material, the reference material or the substrate.

As used herein, and unless stated otherwise, the term “sacrificial layer” refers to a layer of material that is optionally placed between the substrate, and one or more nano- or microstructures (such as e.g. a test nano- or microstructure, a free reference nano- or microstructure or a free sample nano- or microstructure or a double clamped beam). In some embodiments of the present invention, this layer is meant to be removed (e.g. melted or etched away or dissolved away) in order to release the one or more nano- or microstructures (such as e.g. the test nano- or microstructure, the free sample nano- or microstructure and the free reference nano- or microstructure or a double clamped beam). Examples of materials for the sacrificial layer include but are not limited to material of the general formula SiO₂, silicon (e.g. amorphous silicon, crystalline silicon, polysilicon, porous silicon), tungsten, resist materials as known in the art, removable polymeric materials (polyimide for instance), a salt soluble in water, etc. A sacrificial layer is preferably a material which can be removed (e.g. etched away) in a specific solution without damaging the nano- or microstructures (e.g. a test nano- or microstructure, the sample nano- or microstructures and the reference nano- or microstructures or double clamped beam). As used herein and unless stated otherwise, the terms “sacrificial portion” refers to a portion of the substrate which, in some embodiments of the present invention, is meant to be removed (e.g. etched away) in a specific solution without damaging the nano- or microstructure (e.g. a test nano- or microstructure, the sample nano- or microstructures and the reference nano- or microstructures or double clamped beam).

As used herein and unless otherwise specified, the term “substrate” refers to any material on which an optional sacrificial layer, a nano- or microstructure (e.g. a test nano- or microstructure, a free reference nano- or microstructure and a free sample nano- or microstructure or double clamped beam) can be applied. A first factor of merit of a substrate is to be very flat. A second factor of merit of the substrate is to allow some amount of deformation without failure. Example of substrates include but are not limited to semiconductor material e.g. silicon, germanium, group III-V material (such as e.g. GaAs or InP), alumina, glass, quartz, metal (such as e.g. steel), polymeric materials (e.g. PTFE often known as Teflon), etc.

In some embodiments, a “deep etch” creates one or more holes throughout the substrate thickness. In some embodiments, the holes are made before, at the same time or after the release of the micro-structures. Holes can be helpful for instance to look through the sample microstructure with a Transmission Electron Microscope (TEM). In some embodiments, the holes are quadrilateral or hexagonal leading to a truss like structure. In some embodiments, part of the remaining part of the substrate comprises bends or “flat spring” structures. In some embodiments, one or more microstructures are placed above one or more holes in the substrate, or the holes are machined below the microstructures. In some embodiments, one or more microstructures are coupled to the remaining part of the substrate. This is advantageous because the external force and/or displacement applied to the substrate can be scaled down by a factor of e.g. 10 or more before it reaches the microstructures, because it is easier to apply an external force and/or displacement to the larger substrate than to the smaller microstructure, and because the substrate can be subjected to a larger strain without fracture.

As used herein and unless otherwise specified, the terms “etching procedure” refers to a methodology used to release the nano- or microstructure (e.g. the test nano- or microstructure, the free reference nano- or microstructure and the free sample nano- or microstructure or double clamped beam). Preferably, during the etching step the sacrificial layer is removed (or the sacrificial portion of the substrate if no sacrificial layer is used) without attacking the nano- or microstructures (e.g. the test nano- or microstructure, the free reference nano- or microstructure and the free sample nano- or microstructure or double clamped beam). Examples of etching recipes comprise but are not limited to hydrofluoric acid based solutions (under liquid or gas phase) for etching silicon dioxide, Tetramethylammonium hydroxide (TMAH) based solutions for etching polysilicon, silicon or amorphous silicon, hydrogen peroxide (H₂0₂) for etching tungsten, hydrofluoric acid/nitric acid/acetic acid mixture (HNA) based solutions for etching doped silicon or polysilicon, solvent-like solutions for etching polymers such as photoresists, aqueous solution (e.g. water) for disolving water-soluble layers (e.g. gelatine-like layers or salts), Sulfur Hexafluoride (SF₆) for etching monocristalline silicon, amorphous silicon or polysilicon, Xenon Difluoride (XeF₂) for isotropically etching silicon-based materials, among others.

As used herein, and unless stated otherwise, the term “release” refers to the action of removing most of the substrate (or the sacrificial layer if such a layer is present) from adjacent the entity to be released (e.g. the test nano- or microstructure, the free reference nano- or microstructure and the free sample nano- or microstructure or double clamped beam). It is convenient to keep a small portion of this substrate (or the sacrificial layer) under the entity to be released as an anchor point.

As used herein and unless stated otherwise, the term “electromechanical property”, refers to both the effect of an electrical current or field on a mechanical property (e.g. Young's modulus) or state (e.g. strain) and the effect of mechanical stress/strain on an electrical property (e.g. Conductivity, superconductivity) or state (e.g. current gradient), the term “optomechanical property”, refers to the effect of an electromagnetic radiation (e.g. light or laser beam) on a mechanical property (e.g. Young's modulus) or state (e.g. strain) and/or the effect of mechanical stress/strain on an optical property (e.g. refractive index), the term “chemicomechanical property” refers to both the effect of the presence of a chemical species on a mechanical property (e.g. yield stress) or state (e.g. strain) and the effect of mechanical stress/strain on a chemical property (reactivity, absorption, . . . ) or state (eg. absorption gradient), the term “thermomechanical property”, refers to both the effect of temperature on a mechanical property (e.g. yield stress) or state (e.g. strain) and the effect of mechanical stress/strain on a thermal property (e.g. heat capacity, thermal conductivity) or state (e.g. temperature), the term “structuromechanical property”, refers to both the effect of a material structure change (phase transformation, degree of polymerization) on a mechanical property (e.g. Young's modulus, strain hardening capacity, fracture stress) or state (e.g. strain) and the effect of mechanical stress/strain on the structure of the materials (e.g. change of crystal structure, crystallization, change of phase miscibility), the term “nuclear-mechanical property” refers to both the effect of a nuclear reaction on a mechanical property (e.g. yield stress) or state (eg. strain) and the effect of mechanical stress/strain on a nuclear property (e.g. rate of nuclear reaction), the term “multi-physics property” refers to both the effect of any conditions (e.g. stimulus) on a mechanical property (e.g. yield stress) or state (e.g. stress) and the effect of mechanical stress/strain on any material property or state. Examples of multi-physics properties include, but are not limited to, acousto-mechanical properties or magneto-mechanical properties. A multi-physics property thus may refer to the combination of two physical properties of a system.

The invention will now be described by a detailed description of several embodiments of the invention. It is clear that other embodiments of the invention can be configured according to the knowledge of persons skilled in the art without departing from the true spirit or technical teaching of the invention, the invention being limited only by the terms of the appended claims.

In a first aspect, the present invention relates to a system for imposing and determining stresses and strains in one or more nano- or micro-sized samples. Such a system may for example be a micro- or nanotensometer. The system is suitable for handling, studying or treating a micro- or nano-size material sample. The system comprises a device comprising a substrate. The substrate may comprise one or more materials selected from the group consisting of silicon, alumina, germanium, glass, ceramic, organic polymer, group III-V materials and metal, although the invention is not limited thereto. The device aided with an additional means for applying mechanical load, e.g. also referred to as deformation system, may be used to impose and measure a mechanical load on one or more sample nano- or microstructures.

In order to fulfil this function, the device according to an embodiment of the present invention comprises at least one reference nano- or microstructure. The reference nano- or microstructure is directly or indirectly attachable to a sample nano- or microstructure to form a test nano- or microstructure. The one or more reference nano- or microstructures may be directly or indirectly attached to the substrate in such a way that a part of each of said one or more reference nano- or microstructures can stand free. The latter may include that a part of one or more reference nano- or microstructures stands free or would stand free if a sacrificial portion or layer was removed from below said part. An advantageous way to attach reference nano- or microstructures which stand free above the substrate relies on the use of a substrate comprising a sacrificial portion or layer which can be removed to free the reference nano- or microstructures that are lying on it. In embodiments of the present invention, the substrate may thus comprise a sacrificial portion or layer which initially embeds one or more of the reference nano- or microstructures. For instance the substrate may have a portion thereof which is capable of being removed by any means such as but not limited to etching. In embodiments of the present invention, the substrate may be topped by a sacrificial layer, i.e. a layer which is capable of being removed by some means such as but not limited to etching. The sacrificial layer may for instance be created on top of the substrate by chemical or physical deposition or by any other means. Alternatively or in addition thereto, reference nano- or microstructures may be obtained by growing free-standing (e.g. via the use of vapor-liquid-solid mechanism to grow nano-wires of certain materials such as silicon, carbon nanotubes, etc.) or attaching the reference nano- or microstructures by various nano- or micro-technology processing well known to the person skilled in the art such as e.g. nano manipulation and attaching of nano-wire. As indicated, the reference nano- or microstructures can be directly or indirectly attached to the substrate. By directly attached to the substrate, it is meant that the reference nano- or microstructures have a point of contact and attachment with the substrate. By indirectly attached to the substrate, it is meant that the reference nano- or microstructures have no point of contact with the substrate but with another structure itself attached to substrate (e.g. a portion of the optional sacrificial layer, said portion not being meant to be removed or erased).

In an embodiment of the present invention, the device may comprise one or more sample nano- or microstructures, at least one of these one or more sample nano- or microstructures being directly or indirectly attached to one of the one or more reference nano- or microstructure on one hand and to the substrate or to a portion not meant to be removed or erased of the optional sacrificial layer on the other hand. The assembly of a sample nano- or microstructure and a reference nano- or microstructure form a test nano- or microstructure. The sample nano- or microstructure and the reference nano- or microstructure may have identical sections or two sections with two different widths and/or thickness. The sample nano- or microstructure may be attached to the substrate or other structures and may have a part that can stand free in the same or a similar way as described for the at least one reference nano- or microstructure.

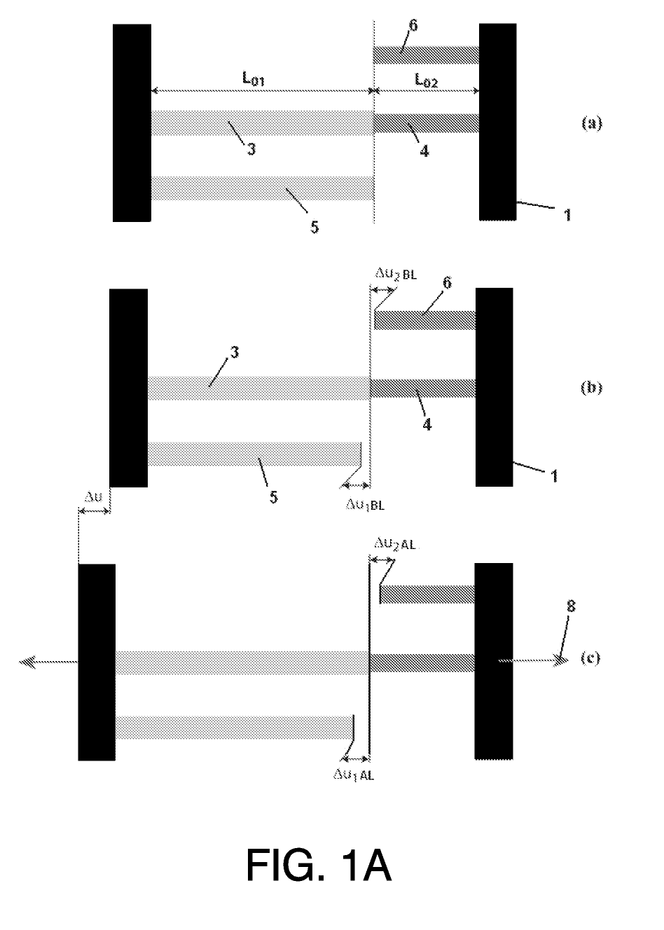

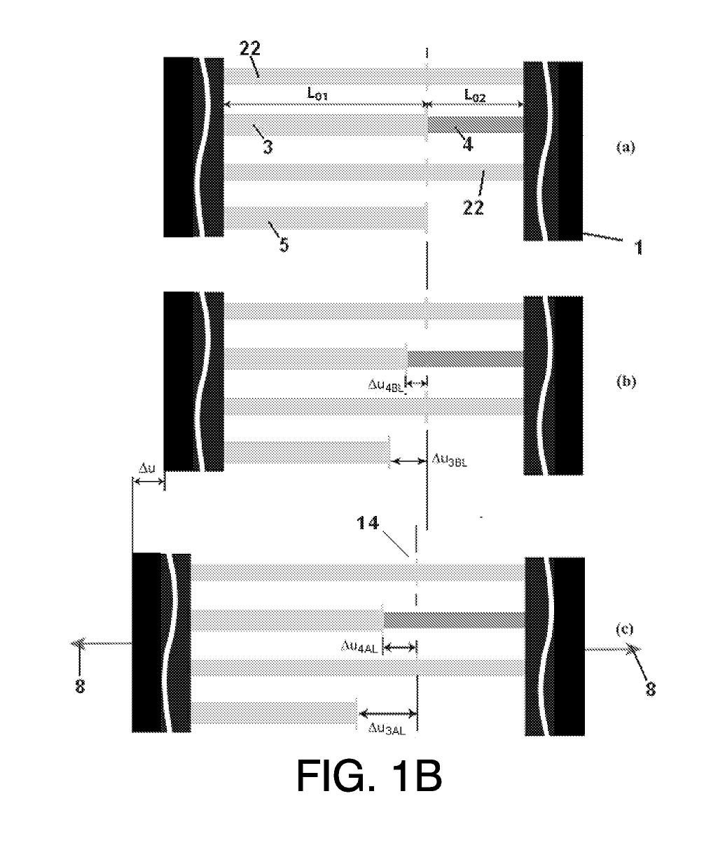

The device furthermore may comprise one or more sample nano- or microstructure not directly connected to the reference nano- or microstructure and/or one or more one or more reference nano- or microstructure not directly connected to the sample nano- or microstructure. These microstructures may be referred to as free nano- or microstructures and may be directly or indirectly attached to the substrate or a portion of the sacrificial layer that will not be erased. Those free nano- or microstructure may have as a purpose to permit an easy measurement of the dimension changes that would occur in their non-free counter parts. The free nano- or microstructure therefore may be of the same length as their corresponding counter-parts present in the test nano- or microstructures. The nano- or microstructures can have different geometry. In an embodiment of the present invention, double clamped nano- or microstructures, such as e.g. double clamped beams comprising cursors, can be used for the purpose of easing the measurement of the dimension changes that would occur within the test nano- or microstructure. Those double clamped beams (22 as shown on FIG. 1B) can be made of the reference material or of the test sample material or of any other sort of material which does not present excessive internal stress that could lead to buckling (compressive material) or fracture (tensile material).

The one or more nano- or microstructures provided in the device may be used as tools to evaluate the stress and/or strain of the sample nano- or microstructures.

A test nano- and microstructure, and thus a sample nano- and microstructure, may be subjected to a mechanical load through an deformation applied to the entire test nano- and microstructure via the actuation points or regions, or to the substrate. In embodiments according to the present invention, the system therefore comprises a means for imposing an external mechanical load, e.g. stress and/or strain, on the test nano- or microstructure. In some embodiments, a reference nano- and microstructure attached to the sample may act as a deformation amplifier applied to the test sample. In an embodiment, the means for imposing the external mechanical load can reversibly impose said mechanical load. This permits for instance to test the fatigue properties of the sample nano- or microstructures. The means for imposing an external mechanical load may alternatively or in addition thereto be mechanical, electrostatic, magnetic or electromagnetic, thermal, chemical, or structural means.

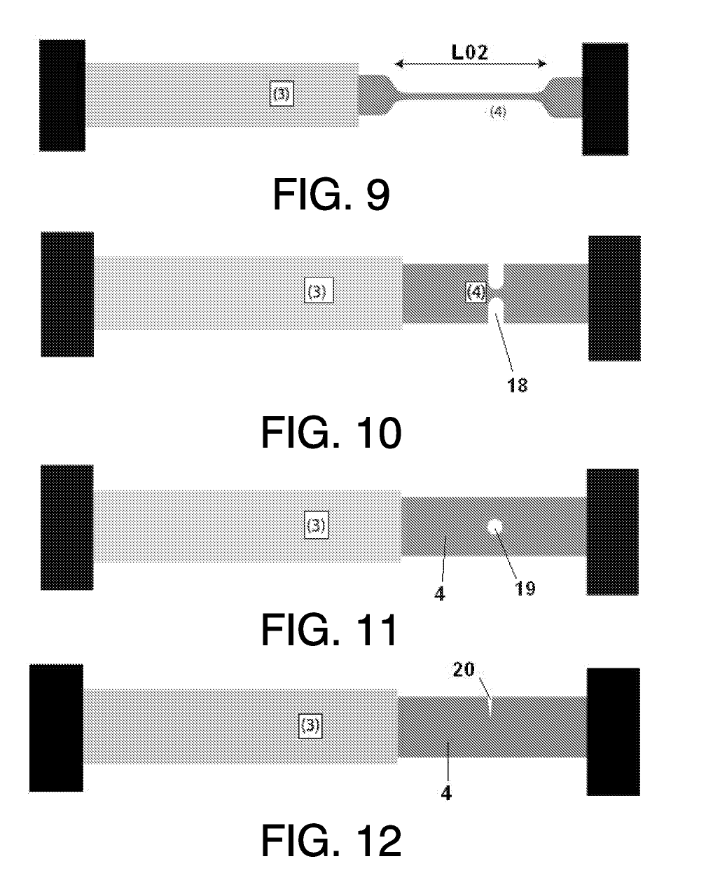

In an embodiment of the invention, the reference structure is made of one or more beams. In another embodiment, the reference structure is made of one or more beams that have an essentially homogeneous tensile or compressive stress and/or strain after release and/or under an external mechanical load applied. “Essentially homogeneous” means that the mechanical behaviour of the structure can be modelled as homogeneous without loss of precision. An example of an essentially homogeneous structure is a “dog bone” shape as shown in FIG. 9. It is an advantage of a reference nano- or microstructure with an essentially homogeneous stress and/or strain that its strain field can be derived from the measurement of displacements or strain. It is another advantage of a reference nano- or microstructure with an essentially homogeneous stress and/or strain that the stress field can be easily derived from the strain or dimensional change information and the knowledge of Young's modulus of the reference material and, more generally, from the stiffness of the reference nano- or microstructure.

In one embodiment of the invention, the mechanical load on the sample nano- or microstructure is a known fraction of the load on the reference nano- or microstructure, the fraction being related to the chosen ratio between the stiffness of the reference nano- or microstructures and the stiffness of the sample nano- or microstructure. It is an advantage of the invention that the external mechanical load applied to the test nano- or microstructure can be scaled up or down to the required level on the sample nano- or microstructure by choosing appropriately said ratio.

The exact value of the external mechanical load imposed by the means has not to be known directly. The direct or indirect knowledge of the dimensional change or strain level of the sample and/or reference nano- and microstructure and/or test nano- and micro-structure and/or dual clamped beams is sufficient.

As an example of an embodiment of an external mechanical load introduced, one can consider the use of a macroscopic deformation machine pulling on the entire substrate, covered by a number of test nano- or microstructures, thereby imposing external stress on the device and therefore also on the test nano- or microstructure and on the sample nano- or microstructures comprised therein. The device or substrate may be adapted with gripping means for gripping the device or substrate for applying external stress. The substrate can be prepared such as to make it less brittle. It is an advantage of applying an external mechanical load to the substrate that said mechanical load can be large. It is an advantage of the invention that, in one embodiment of the invention, the mechanical load on the test nano- or microstructure is a small fraction of the load applied to the substrate, the fraction being related to the chosen ratio between the length of the test nano- or microstructures and the distance between the actuation point of the means to apply the load on said substrate.

As an example of an embodiment of a mechanical load introduced by electrostatic means, one can consider the use of an electrostatic actuator attached directly or indirectly on one side of the test nano- or microstructures and pulling on it.

As an example of an embodiment of a mechanical load introduced by piezoelectric means, one can directly or indirectly connect the test microstructures to a piezoelectric material which under electric current will induce a deformation in the test nano- or microstructure.

As an example of an embodiment of a mechanical load introduced by electromagnetic means, one can consider connecting directly or indirectly the test microstructures to a material moving under the influence of an electromagnetic field. Such a material may for example be a magnet or may be a current wire.

As an example of an embodiment of a mechanical load introduced by chemical means, one can consider the swelling of the entire substrate by a liquid leading to the deformation of each test nano- or microstructure.

As an example of an embodiment of a mechanical load introduced by thermal means, one can consider connecting each test nano- or microstructure to a thermally driven actuator. As another example of an embodiment of a mechanical load introduced by thermal means, one can consider heating or cooling part or all of the substrate.

As an example of an embodiment of a mechanical load introduced by a structural change, one can consider connecting each test nano- or microstructure to a shape memory alloy material, which under a change of temperature will induce a deformation to the test structure.

In some embodiments, the substrate, the test micro- or nano-structure(s) may be arranged for traction measurement. In some embodiments, the test nano- or microstructure may be arranged for compression measurement. In still other embodiments the test nano- or microstructure(s) may be arranged for shear measurement.

The system may be used for providing dimensional information on the sample nano- or microstructure, e.g. for determining one or more dimension changes within the test micro- or nanostructure. Different properties, such as for example mechanical properties of the sample may be derivable from the provided dimensional information. Typically, physical properties, such as for example strain and/or stress, may be directly inferred from the dimensional information. In one embodiment, the knowledge of the strain and/or the stress for different measured dimension changes permits the generation of the stress-strain curve, optionally up to the fracture strain. According to embodiments of the present invention, the system therefore may comprise direct or indirect means for providing dimensional and/or strain information on the one or more sample and/or reference and/or test nano- or microstructures and/or double clamped beam. Means for providing dimensional and/or information may comprise for example the provision of a reference mark or scaling allowing the derivation of a relative or absolute change of a reference point in the microstructure, such as e.g. an endpoint or connection point, with respect to the reference mark or scaling. The means for deriving a dimensional change may comprise at least one free nano- or microstructure, allowing one to derive whether a reference structure within a test nano- or microstructure has a dimensional change larger or smaller than the free reference nano- or microstructure and thus providing relative dimensional information. Such a free nano- or microstructure may be a nano- or microstructure not subject to the external stress applicable to the test nano- or microstructure. Similarly, the means for deriving a dimensional change further may comprise a free sample microstructure, allowing one to derive whether a sample structure within a test nano- or microstructure has a dimensional change larger or smaller than the free sample microstructure and thus providing relative dimensional information. The system may be adapted for deriving from the dimensional change in combination with the applied stress a physical property characterizing the nano- or microstructure material. The system for deriving a dimensional change in some embodiments also may be or comprise an optical source and detection system for detecting such changes, such as e.g. a camera, an optical detector, a microscope, etc. A processor for determining such a physical property based on this information may be provided. Such a processor may operate based on a predetermined algorithm, according to a neural network, using predetermined rules, etc. The processor may allow obtaining physical property information in an automatic and/or automated way. Such a processor also may be external to the system, i.e. not being part of the system. The processor may comprise a computing unit for computing the physical property of interest.

On top of imposing a deformation/stress into the test nano- or microstructure by various physical means, the sample nano- or micro structure can be subjected to various physical or chemical additional effects via additional stimulus. The stress/strain state of the sample nano- or microstructure may change with the additional stimulus. The possible effect of the additional stimulus on the surroundings of the sample, and in particular on the reference micro and nanostructure preferably is known independently or is negligible, or is avoided. In order to apply such a stimulus, embodiments of the present invention may comprise a means for applying such a stimulus. Chemical stimulus may for instance take the form of placing the sample nano- or microstructures in presence of reactants, so that a chemical reaction or absorption takes place that induces stress in the sample structure (such as the absorption of hydrogen into Palladium layer). Physical stimulus encompass, but are not limited to, optical, electrical, magnetic, thermal, nuclear and acoustical stimulus. Optical stimulus may for instance take the form of sending a laser beam on the sample nano- or microstructures, so that an optical interaction takes place that modifies the stress. Acoustical stimulus may for instance take the form of creating an acoustic wave in the sample material. Thermal stimulus may for instance take the form of changing the temperature of the sample nano- or microstructures by local heating. Nuclear stimulus may for instance take the form of bombarding the sample with various sorts of particles.

In an embodiment, the system may furthermore comprise means for determining (or inferring through modeling) the additional electrical, optical, chemical, acoustic, thermodynamic, structural, nuclear, or quantum mechanical stimulus imposed globally to the substrate or locally to the test micro- or nanostructures or to the sample micro- or nanostructures. By way of example, embodiments of the present invention not being limited thereto, a means for determining an electrical property may be provided. In one embodiment, one or more sample micro- or nanostructures are machined into a loop connected to electrical connecting points, allowing the measurement of conductivity in the sample nano- or microstructures. Alternatively or in addition thereto, an optical sensor, a detector for chemical properties, an acoustic sensor, a heat sensor, etc. may be provided.

In one embodiment, the device may be used for determining one or more dimensional changes for several electrical, optical, chemical, acoustical, thermodynamical, structural, nuclear or quantum mechanical conditions imposed on the sample, permitting the determination of multi-physics property. In other embodiments, a multi-physics state or property is measured for each dimension changes and thus for each stress or strain mechanical condition, permitting the determination of multi-physics property.

The properties which can be measured with the technique include, but are not limited to: elastic moduli, yield stress, fracture stress, strain hardening capacity, strain rate sensitivity, fatigue resistance, ultimate tensile stress, strain at necking, resistance to elastic or plastic buckling load, fracture strain, fracture toughness, JR curve, essential work of fracture, fatigue resistance (da/dn versus dK curves or Wolher curves) as well as all of these properties under environmental condition as well as the coupled electromechanical, optomechanical, chemicomechanical, acousticomechanical, thermomechanical, structuromechanical, nuclear mechanical, and/or quantummechanical properties.

In an embodiment of the invention, multiple elementary machines with identical and/or different dimensions are used. This allows, with one large set of nano- or microstructures, the generation of valid results (there will always be nano- or microstructures in the valid design range), and/or of statistically representative data, and/or of results associated to different geometries and loading conditions.

In a further aspect of the invention, the system is used as a sensor to derive the electrical, optical, chemical, acoustic, thermodynamical, structural, nuclear or quantum mechanical condition in the environment of the material to be stressed.

In a further aspect, the present invention relates to a method for manufacturing a device for characterizing a sample nano- or microstructure comprising the steps of obtaining a substrate and attaching one or more test nano- or microstructures to the substrate in such a way that a part of said test nano- or microstructure stand free or can stand free, e.g. after removal of a sacrificial portion or layer. Obtaining a substrate may be performed in any suitable way, i.e. it may comprise obtaining a suitable substrate or preparing a substrate.

The method further may comprise providing one or more means for imposing an external mechanical load on said test nano- or microstructure, wherein said external mechanical load is externally applied on said micro- or nanostructures by the means such as mechanical, electromagnetic, optical, chemical, acoustic, thermodynamic, structural, nuclear or quantum mechanical means. The means may be any suitable type of means for applying an external mechanical load. In one embodiment, the means for imposing an external mechanical load is a mechanical means, whereby e.g. gripping means are provided in the device for gripping the device and apply an external stress. In another embodiment, this may be a magnetic or electric field generator for applying a magnetic or electric force on the microstructure, the device or an object that can be charged or through which a current can be sent for inducing an indirect an electrical force thereon which may be converted in a mechanical force on the microstructure.

The method furthermore may comprise providing a means for providing direct or indirect dimensional or stress information on at least one of said one or more sample and/or reference nano- or microstructure and/or test structure and/or double clamped beam. The latter may comprise providing a reference structure for which the mechanical changes under induced stress are known, providing a scaling on the substrate in order to be able to measure an amount of shift of a point in the test nano- or microstructure with reference to the scale, etc. In other embodiments the latter may comprise providing optical source and detection systems for actually determining the dimensional information.

In an embodiment of the present invention wherein the device or system for assisting in characterization of nano- or micro-structures comprise a test nano- or microstructure (itself comprising a reference nano- or microstructure, a sample nano- or microstructure) and a sacrificial layer, a substrate is prepared with three layers on top of it. In this embodiment, a sacrificial layer is created (by chemical or physical deposition or by any other means) on top of the substrate and a layer of reference material with known Young's modulus is created (by chemical or physical deposition or by any other means) on top of the sacrificial layer. The layer of reference material is patterned into a reference nano- or microstructure either during deposition or by lithographical means after deposition. A typical reference nano- or microstructure is a long beam, i.e. a feature having a dimension in one direction substantially larger than the dimension in the other directions. A sample nano- or microstructure is created (by chemical or physical deposition or by any other means) in such a way that it is connected to the reference nano- or microstructure on one hand, and to the sacrificial layer or to the substrate on the other hand. The nano- or microstructures can be made at least partly free by removing the sacrificial layer. Alternatively or in addition thereto nano- or microstructures also may be made using other techniques, e.g. by growing nanowires, nanotubes etc. directly on the substrate. Alternatively or in addition thereto nano- or microstructures also may be made using other techniques, e.g. by growing nanowires, nanotubes etc. and later attaching them to the substrate. A typical sample nano- or microstructure is a long beam, i.e. a feature having a dimension in one direction substantially larger than the dimension in the other directions. It is patterned either during deposition or after deposition, e.g. by lithographical means. In one embodiment, the sample micro- or nanostructure is created before the reference micro- or nanostructure.

In an embodiment of the present invention, many elementary test nano- or microstructures (e.g. ten or more or even hundred or more) may be built on the substrate, each having their specific dimensions (e.g. length, width, thickness) of the reference nano- or microstructure and/or of the sample nano- or microstructure. The geometry (straight beams, notched beams, samples with holes) of the sample nano- or microstructure can also be varied.

A free reference nano- or microstructure, preferably of the same dimensions as the reference nano- or microstructure comprised in the test nano- or microstructure can be created following the process used for creating the reference nano- or microstructure, the only difference is that no sample nano- or microstructure is attached to the reference nano- or microstructure in this case. Similarly, a free sample nano- or microstructure, preferably of the same dimension as the sample nano- or microstructure comprised in the test nano- or microstructure, can be created following the process used for creating the sample nano- or microstructure. The only difference is that no reference nano- or microstructure is attached to the free sample nano- or microstructure in this case.

In one embodiment of the present invention wherein use is made of a sacrificial layer for generating the free nano- or microstructures, the various structures are chemically and/or physically released by an etching fluid (e.g. an etching solution or gas), i.e. by removing a portion of the substrate or of the sacrificial layer located under the microstructures (e.g. the test nano- or microstructure(s) and/or the free reference nano- or microstructure(s) and/or the free sample nano- or microstructure(s), and/or the double clamped nano- or microstructure(s)) in order to free them. The nature of the etching method based on liquid or gas solution depends on the nature of sacrificial layer and/or the substrate, the reference material and material to be stressed.

In some cases, it may happen that the various nano- or microstructures have small to large internal stress and/or internal stress gradients, generated by the deposition processes. Once freed, the connection points in the test nano- or microstructure may move in and/or out of plane due to the said internal stress or internal stress gradients. Similarly, the end point of the free reference nano- or microstructure and of the free sample nano- or microstructure may move in and/or out of plane. These displacements can be measured relatively to the substrate to infer the internal stress and/or internal stress gradient, if any. Other techniques for determining the internal stress and/or internal stress gradient are known to those skilled in the art. The knowledge of this stress and/or stress gradient, if significant, may be used in subsequent calculations.

In a further aspect, the present invention relates to a method for characterizing one or more sample nano- or micro-structures (e.g. determining one or more physical properties). The method may be performed using a system as described above in embodiments according to the first aspect of the present invention, although the invention is not limited thereto. Such a method may comprise imposing external stress and/or strain on a test nano- or microstructure comprising a reference nano- or microstructure directly or indirectly attached to a sample nano- or microstructure. The reference nano- or microstructure is directly or indirectly attached to a substrate so as to stand free with respect to the substrate. The method further comprises directly or indirectly providing dimensional and/or strain information on the sample and/or reference and/or test nano- or microstructure based on a response to said imposing stress and/or strain. By way of illustration, standard and optional steps of an exemplary method will be described in more detail.

The method may comprise obtaining a device with a test nano- or microstructure comprising a reference nano- or microstructure directly or indirectly attached to a sample nano- or microstructure. The reference nano- or microstructure is directly or indirectly attached to a substrate so as to stand free with respect to the substrate. The latter may be for example by obtaining a ready made system or may be manufacturing a substrate, e.g. according to any related embodiment presented in this description. In some cases, where a substrate with an unremoved sacrificial portion or layer is used for obtaining the nano- and/or microstructures, the method further may comprise removing the sacrificial portion or layer.

The method comprises imposing an external mechanical load applied on the one or more test nano- or micro-structures on the device. Applying an external mechanical load may be performed in any suitable way, e.g. via mechanical, electrical, acoustical, magnetic, chemical, thermal, optical, structural, nuclear, quantum mechanical or other means or a combination thereof. In an embodiment, the method may furthermore comprises placing the sample nano- or micro-structures in one or more particular physical conditions (e.g. under one or more stimulus), Examples of such particular physical conditions are an electrical, magnetic, chemical, thermal, optical, structural, nuclear, quantum mechanical or other condition or a combination thereof. The sample nano- or micro-structures can be stressed under different loading configurations. One can divide testing configurations into “homogenous conditions” and “non-homogenous conditions. The homogeneous test conditions refer to sample nano- or micro-structures in which the stress and/or strain fields will be homogeneous inside one well defined section of the sample nano- or micro-structures. Examples are sample nano- or micro-structures deformed under uniaxial tension, uniaxial compression, biaxial tension or shear. The non-homogeneous test conditions refer to sample nano- or micro-structures involving geometrical features leading to stress and/or strain gradients. A mechanical load may be directly or indirectly imposed to the test nano- or microstructure. It can be either a global strain of the substrate and its nano- or microstructures, or a strain directly imposed locally to the test nano- or micro-structures via the actuation points, but not to the free sample nano- or microstructure nor the free reference nano- or microstructure.

The method also comprises obtaining dimensional information from the means for providing dimensional information. For instance, the method may comprises deriving dimensional information of at least one of the one or more nano- or micro-structures and deriving based thereon and, a physical property of the nano- or micro-materials. The determined property may be one or more mechanical and/or electromechanical and/or optomechanicalo, and/or chemicomechanical and/or acousticomechanical and/or thermomechanical and/or structuromechanical and/or nuclearmechanical and/or quantummechanical properties. Obtaining dimensional information may comprise deriving whether a sample nano- or microstructure is changing in a predetermined direction more or less than a free sample microstructure, may comprise whether a reference microstructure is changing in a predetermined direction more or less than a free reference microstructure, may comprise determining a variation in a dimension in a predetermined direction of a reference microstructure or a sample microstructure, etc. For example in the case of homogeneous loading conditions, the extraction of mechanical data may involve determining one or more dimension changes. The displacement of a free point or a connection point in a nano- or microstructure when the microstructure is under external strain may be measured relative to the position of the free point or connection point in the nano- or microstructure when it is not under external mechanical load, thus also allowing the derivation of a dimensional change. In some embodiments, the latter may be done for a free point of a reference nano- or microstructure and/or for a free point of a sample nano- or microstructure and/or for a connection point between sample and reference portion of a test nano- or microstructure.

Obtaining dimensional information may also be done by comparing a sample nano- or micro-structure to another nano- or micro-structure of a known material with the same geometry. In particular, the known material may be the same as the sample, but produced in slightly different conditions. In particular, the comparison may be limited to checking whether both micro- and nanostructures have been broken by the stress, or not. This is particularly advantageous in quality control of a production process.

Obtaining dimensional information by determining the displacement also for a reference nano- or microstructure allows the determination of the physical properties without knowing the exact force applied to the structures. These measurements provide the value of a physical property such as e.g. the strain in the reference nano- or microstructure and from the knowledge of the Young's modulus of the reference material, give the induced stress in the reference nano- or microstructure. The stress in the sample nano- or microstructure is directly inferred from load equilibrium and optionally from the knowledge of the sections of the reference and sample nano- or microstructures. In some embodiments, the displacement of the connection point in a test nano- or microstructure may be measured relative to the end point of the free reference nano- or microstructure. Such relative measurements of variations in dimension also allow to determine a difference in dimensional change.

Alternatively, measurement of the displacement may be performed for the sample nano- or microstructure without measurement on reference structures, whereby a physical property can be derived from the change in dimension combined with the size of a known applied force.

More generally, from the derived variation in dimension, the induced stress can be derived and the value of the strain in the sample nano- or microstructure may be obtained. Thus the stress and the strain in each sample nano- or microstructure can be inferred, and can be plotted as one point of the stress strain curve of the material to be stressed. Other properties of the material under stress, such as electrical, physical, optical, chemical, acoustic, thermodynamic, structural, nuclear or quantum mechanical properties, can be measured by traditional means and related to the intensity of the stress.

Thus full stress strain curves can be generated up to the fracture strain by increasing the external load. The principle is the same independently of the homogeneous loading type, i.e. whether it is for instance uniaxial tension shear loading, compression or biaxial loading. In all these cases, stress and/or strain may be extracted directly or indirectly from dimension changes and/or strain measurements. Other loading types can be applied as well such as chemical loading (e.g. exposing the device to a particular chemical environment), thermal loading (e.g. exposing the device to a different temperature), optical loading (e.g. exposing the device to a laser beam), structural loading (e.g. exposing the device to a phase change), nuclear loading (e.g. exposing the device to a nuclear decay, fission or fusion reaction), or quantum mechanical loading (e.g. exposing the device to a particle beam).

In the case of non-homogeneous loading conditions, different sort of dimension change measurements can be performed depending on the type geometry. For instance, opening of notches, change of dimension of holes, crack opening displacement. Digital image correlation can also be employed to determine full strain fields.

To perform a measurement, the reference nano- or microstructure is preferably long enough to amplify the strain imposed to the test sample. The sample nano- or microstructure must be long enough for the resolution of the displacement measurement technique to be accurate enough. The reference micro or nanostructure must have a stiffness (product of section area by Young's modulus) not too large with respect to the stiffness of the sample micro- or nanostructure otherwise the accuracy on the determination of the stress will be poor. The fabrication of many test nano- or microstructure with different dimensions (different absolute length and ratio of cross-section area) on a single substrate may allow using the same design for different choice of materials to be stressed and their thicknesses. In such a case, there will always be a sub-set of test nano- or microstructure respecting the design criterion.

In a further aspect of the invention, the system has one or more means to apply an external mechanical load on a test nano- or microstructure, and thus a sample nano- or microstructure, in order to obtain a sample material with one or more desired electromechanical, optomechanical, chemimechanical, acousticomechanical, thermomechanical, structuralo-mechanical, nuclearmechanical or quantummechanical properties. In some embodiments of the invention, a mechanism can quickly turn off one or more means to apply said external mechanical load, e.g. for security reason. In one embodiment of the invention, one or more servomechanisms monitor the displacements of one or more microstructures and control one or more means to apply said external mechanical load in order to maintain a desired property or state of the material to be stressed.

Based on the above-described general principle, several particular embodiments and examples of the present invention will now be described by reference to FIGS. 1 to 20, the present invention not being limited thereto.

In one particular embodiment of the present invention, the micro- or nanomachine is a tensile test machine in which the various nano- or microstructures are made of simple beams. The principles of the exemplary system are summarized in FIG. 1A. FIG. 1A also allows relating the definitions given in a previous section to a specific exemplary design for the sake of illustration. In FIG. 1 (a) (b) and (c), a system according to an embodiment of the present invention is schematically represented. The means for imposing an external mechanical load on the device is conceptually represented by the arrows (8). In FIG. 1A (a) a device according to the present invention is represented comprising a free sample nano- or microstructure (6) (here a beam) attached at one end to an anchor portion of the substrate (1) and resting on a sacrificial layer (not shown). Also represented is a test nano- or microstructure composed here of a sample nano- or microstructure (4) and a reference nano- or microstructure (3). At the lower part of FIG. 1A (a), a free reference nano- or microstructure (5) is also represented. The initial length L₀₁ of the reference nano- or microstructure (3) is in this particular embodiment equal to the length of the free reference nano- or microstructure (5). The initial length L₀₂ of the sample nano- or microstructure (4) is in this particular embodiment equal to the length of free sample microstructure (6). FIG. 1A (b) represents this same device after release, i.e. after that the sacrificial layer has been etched away. Small displacements Δu_{1BL} and Δu_{2BL} of the components of the test nano- or microstructure relative to their free counterparts can occur due to internal stress and are shown by the double arrows. The letters “BL” means that those displacements are measured “before loading”, i.e. before imposing for example stress on the device. FIG. 1A (c) shows the situation where external mechanical loading (8) has been applied to the device, causing a total displacement Δu which is positive when the total length increase. Displacements Δu_{1AL} and Δu_{2Al} are also indicated. “AL” stands here for “after loading”.

In FIG. 1B (a) (b) and (c), a system according to another embodiment of the present invention is schematically represented. The means for imposing an external mechanical load on the device is conceptually represented by the arrows (8) whether the deformation is imposed globally on the substrate or more locally. In FIG. 1B (a) a device according to the present invention is represented comprising a free reference nano- or microstructure (5) (here a beam) attached at one end to an anchor portion of the substrate (1) and resting on a sacrificial layer (not shown). Also represented is a test nano- or microstructure composed here of a reference nano- or microstructure (3) and a sample nano- or microstructure (4). Also represented are double clamped beams (22) attached on both ends to the substrate. Those double clamped beams (22) can be made of the reference material or of the test sample material or of any other sort of material which does not present excessive internal stress that could lead to buckling (compressive material) or fracture (tensile material). The initial length L₀₁ of the reference nano- or microstructure (3) is in this particular embodiment equal to the length of the free reference nano- or microstructure (5). The initial length of the sample nano- or microstructure (4) is noted L₀₂. FIG. 1B (b) represents this same device after release, i.e. after that the sacrificial layer has been etched away. Small displacement Δu_{3BL} of the free reference nano- or microstructure relative to the fixed beam are possible due to inherent internal stresses. The letters “BL” means that this displacement is measured “before loading”, i.e. before imposing e.g. external stress on the device. The displacement Δu_{3BL} is defined as negative if the reference nano- or microstructure contracts. The displacement Δu_{3BL} allows extracting the mismatch strain ε₁ₘᵢₛ (resulting from possible internal stress) present inside the reference material in the following way:

$${ɛ}_{1 mis} = ln ( 1 + \frac{Δ {u}_{3 BL}}{{L}_{01}} ) . \qquad ( 1 )$$

In another embodiment, the mismatch strain can be determined owing to other methods such as the wafer curvature method (Stoney method) or with other micro or nanostructures, known by the person skilled in the art. Also, the possible mismatch strain associated to the test sample material ε₂ₘᵢₛ can be obtained using one the aforementioned method.

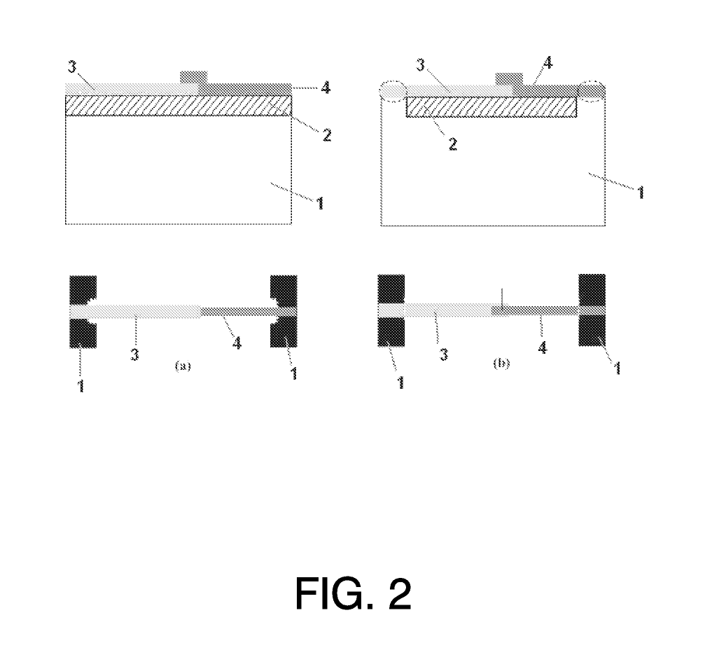

As schematically shown in FIG. 2(a), in a particular embodiment of the present invention, a sacrificial layer (2) and a layer of a reference material (3) with a known Young's modulus Ef are deposited or bonded successively on a substrate (1) (typically a stiff and thick substrate, e.g. Si, steel, glass). In this embodiment of the invention, the sacrificial layer (2) covers the full surface of the substrate. In another particular embodiment of the invention depicted in FIG. 2 (b), the sacrificial layer (2) is deposited on a pre-patterned substrate (1) comprising trenches having preferably been polished, limiting the presence of the sacrificial layer (2) to specific regions. This is advantageous because the anchors of the nano- or microstructures are better defined geometrically, resulting in more homogeneous strain fields and more precise measurement of dimensions. The dashed circled portions show the anchor region where the reference nano- or microstructure (3) and the sample nano- or microstructure (4) are attached to the substrate (1). In another embodiment of the invention, the substrate directly plays the role of the sacrificial layer. In one embodiment of the present invention, after deposition of the reference material, a lithography of the reference material (3) is made. The reference material (3) is then etched in order to create the reference nano- or microstructure (3), e.g. beams of different length and width. The etching step may be followed by a deposition (e.g. by evaporation, sputtering, electroplating, spin coating, chemical or physical vapour deposition, Atomic layer deposition, etc.) of the material to be stressed (4). In one embodiment of the invention, a lithography and etching is performed in order to create the sample nano- or microstructure. In another embodiment of the present invention, the sample nano- or microstructure is directly deposited with the final pattern (geometry and dimensions) owing to the use of microgrids. In another embodiment, a thick resist layer is first deposited and patterned via photolithography and etching, then the material to be stressed is deposited on the resist; when the resist is removed, the material to be stressed that lies above it is also removed, leaving only the material to be stressed where there is no resist (“lift-off” process). In another embodiment of the present invention, the material to be stressed (4) is deposited before the reference material (3). The bottom of FIGS. 2 (a) and (b) show the test nano- or microstructures obtained after deposition and lithography of the reference material (3) and the material to be stressed (4). In another embodiment of the invention, the sample nano- or microstructure (4) plays the role of the reference nano- or microstructure (if its Young's modulus is known) which avoids all the steps involved with the deposition and patterning of an extra reference sample. In that case, the reference and the sample nano- or microstructures are made of the same material and may form a single entity. As a preferred feature, when the sample nano- or microstructure (4) plays the role of the reference sample (3), the geometry of the test nano- or microstructure is still given by the schematic of FIGS. 1A and 1B and 2 and may involves two sections with two different widths or thickness. These sections can be obtained for instance via lithography or the use of microgrids. An example of physical property that can be determined in the embodiment of FIG. 1A or FIG. 1B is a stress-strain curve, e.g. a full stress-strain curve up to the fracture strain.

In one embodiment of the invention, the sacrificial layer is etched away. In another embodiment, no sacrificial layer is deposited and the nano- or microstructures are deposited directly on the substrate, and they are released by etching the substrate below them.

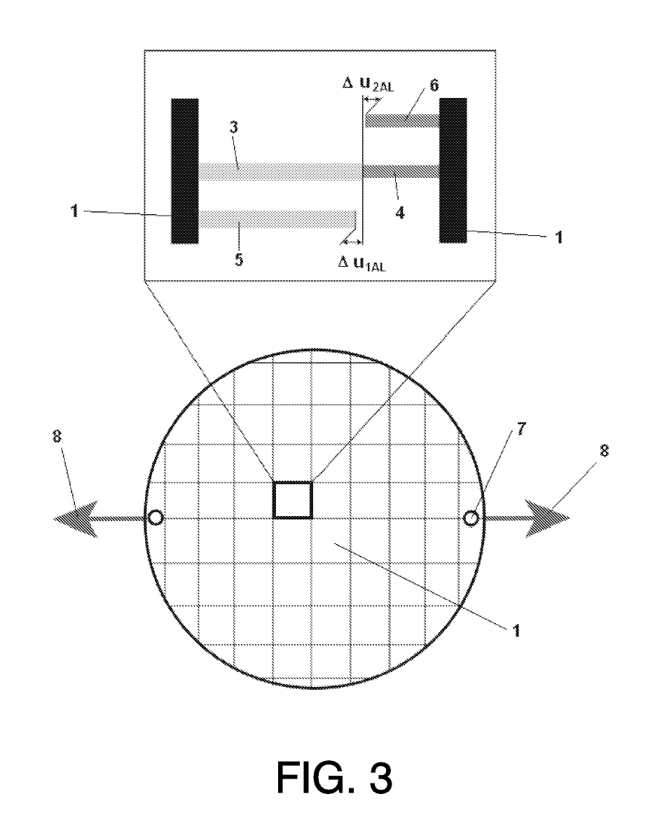

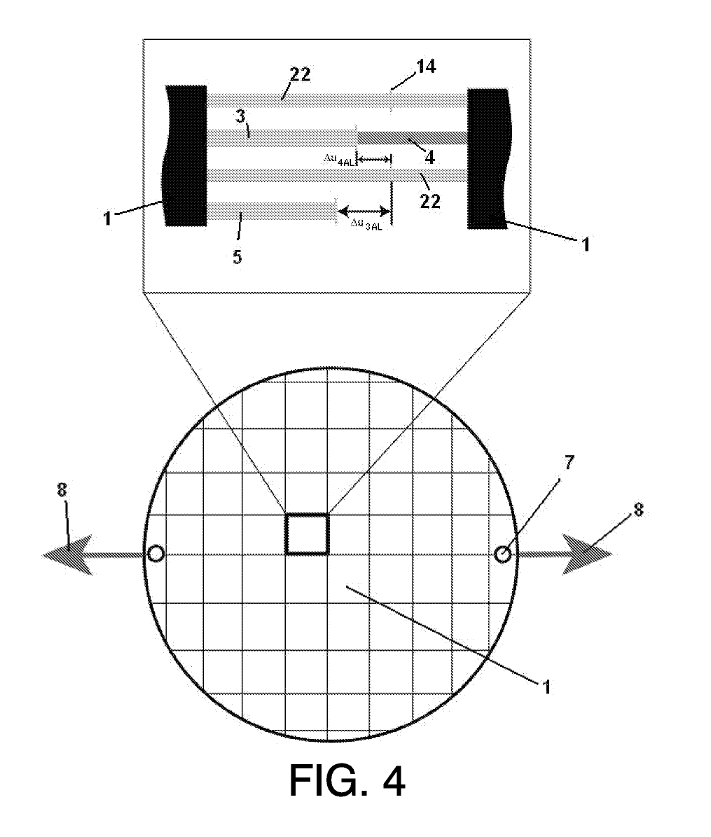

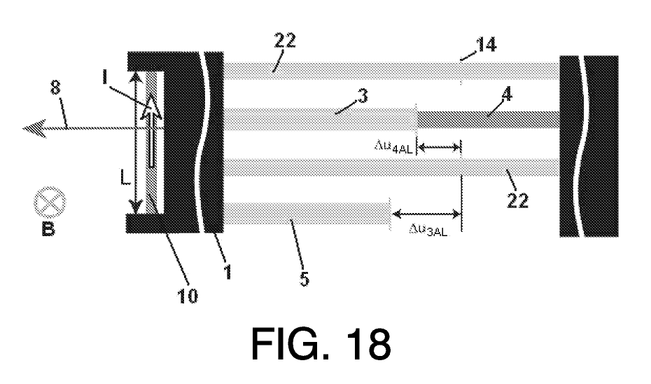

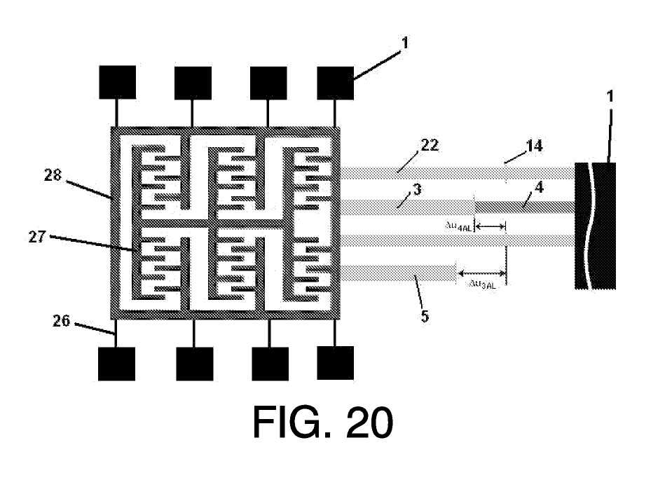

FIG. 1A (c) and FIG. 1B (c) show the situation where external deformation (8) has been applied to the device, causing a total displacement Δu and associated strain imposed to the test micro or nanostructure ε_{sub} equal to

$${ɛ}_{sub} = ln ( 1 + \frac{Δ u}{{L}_{0}} ) \qquad ( 2 )$$

where L₀=L₀₁+L₀₂. In one embodiment of the invention, the global deformation sub is imposed to the substrate (1), see FIG. 3 and FIG. 4 for an illustration in the case of circular wafertype substrate (1). Different means can be used to impose an external mechanical load leading to the overall deformation such as, but not limited to, a macroscopic tensile loading stage, biaxial loading stage, bending stage or by dilatation of the substrate through for instance swelling by a liquid. In embodiments where many test nano- or microstructures are fabricated on the substrate, they all undergo the overall strain applied to the substrate. The applied strain is preferably aligned with the test nano- or microstructure direction. In an embodiment of the present invention (see FIG. 18), the means for imposing an external mechanical load on the test nano- or microstructures (3, 4) comprise a long conductive beam (10) which, in the presence of an AC or DC current (I) and under the action of magnetic field B polarized in the right direction will produce a displacement owing to the Lorentz force. The appropriate direction of the magnetic field thereby may be such that the Lorentz force acts in a length direction of the microstructures. The Lorentz force can be calculated by the following equation: F=I*B*L, wherein F is the Lorentz Force in Newton, B is the magnetic field in Tesla, I is the current in Ampere and L is the length of the conducting wire. For instance it permits to determine stress/strain couples and to calculate e.g. the young modulus of the sample nano- or microstructure. Another particular embodiment of the invention for applying a local displacement rely on using electrostatic loading, e.g. by applying an electrostatic field on a charged object connected to the microstructure or on a charged microstructure. Examples of microstructures which can act as an means for imposing an external mechanical load on said test nano- or microstructures are shown in FIGS. 17 and 20. In FIG. 17, a potential difference between a fixed microstructure 24 and a mobile substrate microstructured part 1 imposes an external stress and/or strain to the test microstructure (3, 4). In FIG. 20, an electrostatic micromachine is used as means for externally imposing a mechanical load on said test nano- or microstructures. The electrostatic micromachine comprises fixed (anchor) parts of the substrate (1) to which mobile microstructures (28) are attached via springs (26). The mobile microstructures (28) are placed relatively to a fixed microstructure (27) in such a way that a potential difference between said fixed microstructures (27) and said mobile microstructures (28) would trigger a movement in the mobile microstructures (28) which will serve as the means for externally imposing a mechanical load on said test nano- or microstructures.

In one embodiment, the strain ε_{sub} as defined by eqn. (2) can be determined through the measurement of the displacement Δu_{3AL} as defined in FIG. 1Bc (by convention Δu_{3AL} is negative when observed as in FIG. 1Bc) as

$${ɛ}_{sub} = ln ( exp ( {ɛ}_{1 mis} ) - \frac{Δ {u}_{3 AL}}{{L}_{01}} ) \qquad ( 3 )$$

In another embodiment corresponding to a strain directly applied to the substrate, the strain ε_{sub} is equal to the strain applied to the substrate which can be evaluated from standard procedures associated to the technique used to impose this strain, typical of a standard macroscopic mechanical loading method, for instance through strain gages attached to the substrate, or using a nanometer accurate positioning table or through extensometers. In another embodiment, the displacement Δu can directly be measured with respect to a fixed point on the substrate. The person skilled in the art can infer the strain ε_{sub} from other dimensional and/or strain changes, such as Δu_{1AL}.

The sample nano- or microstructures can have different geometries and can be stressed under different loading configurations. One can divide testing configurations into “homogenous conditions” and “non homogenous conditions. The homogeneous test conditions refer to sample in which the stress and/or strain fields will be homogeneous inside one well defined section of the sample. Examples are given by samples deformed under uniaxial tension, uniaxial compression, biaxial tension or shear. The non-homogeneous test conditions refer to sample involving geometrical features leading to stress and/or strain gradients.

The analysis of the mechanical response of the sample nano- or micro-structure under homogeneous loading conditions requires determining dimension changes imposed to the test nano- or microstructure (i.e. to the reference nano- or microstructure(s) and/or sample nano- or microstructure(s) composing it). The principle for uniaxial tension tests is described in the following. The analysis of other homogeneous conditions (shear, biaxial loading, compression) is very similar and changes only by details.

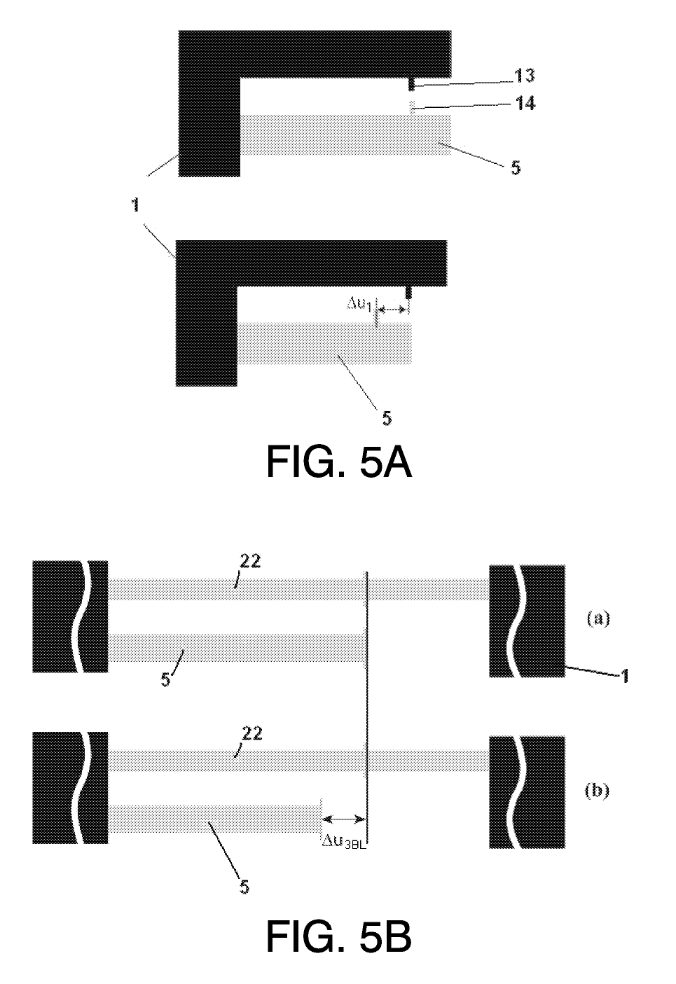

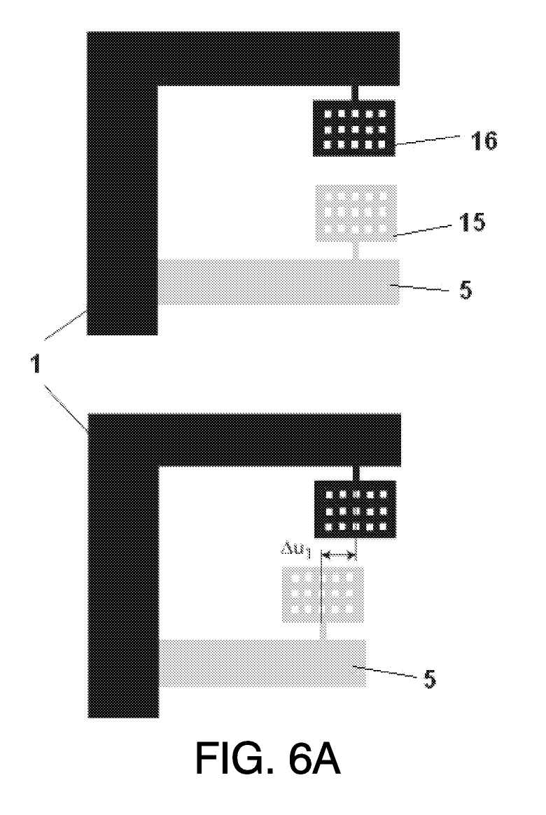

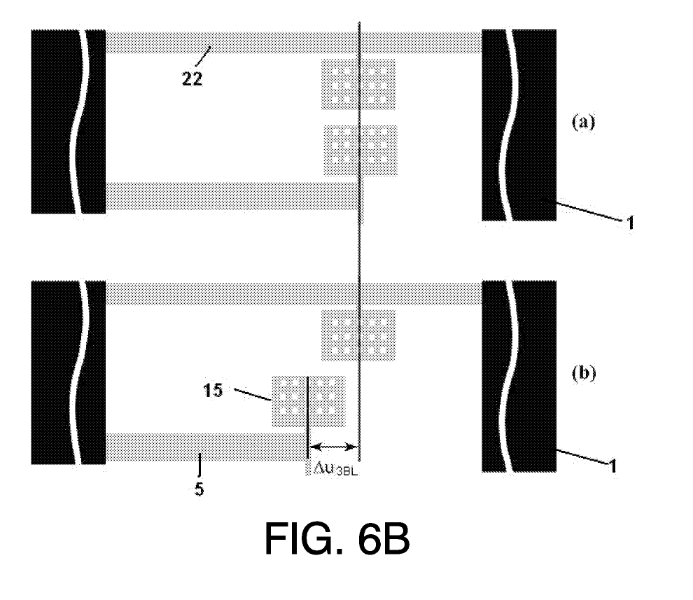

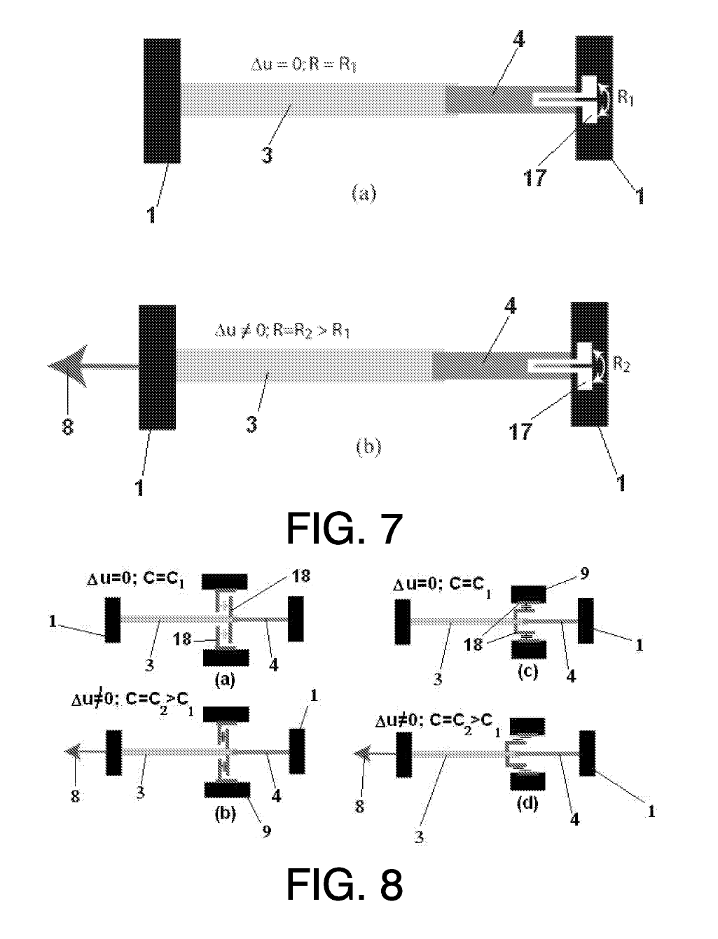

In one embodiment of the invention, the determination of the loading conditions, i.e. force and overall deformation, into the sample nano- or microstructure requires the measurement of two relative displacements. In one embodiment of the invention, the relative displacements Δu_{1AL} and Δu_{2AL}, (see FIG. 1A), or Δu_{3AL} and Δu_{4AL} (see FIG. 1B), are measured from direct microscopic observations or other indirect means. In another embodiment of the invention, the relative displacements Δu and Δu_{2AL} (see FIG. 1A) or Δu and Δu_{4AL} (See FIG. 1B), are measured from direct microscopic observations or other indirect means. In another embodiment of the invention, the relative displacements Δu and Δu_{1AL} (see FIG. 1A), or Δu and Δu_{3AL} (See FIG. 1B), are measured from direct microscopic observations or other indirect means. In another embodiment of the invention, only Δu_{1AL} or Δu_{2AL} or Δu_{3AL} Δu_{4AL} is measured from direct microscopic observations or other indirect means, when ε_{sub} is known independently, as explained above. In another embodiment of the invention, a free sample micro or nano-structure is added to previously defined embodiment in order to quantify possible mismatch strain ε₂ₘᵢₛ resulting from possible internal stress in the sample. In another embodiment of the invention, the free-reference nano- or microstructure and possible free sample nano- or microstructure have a different original size than respectively the reference nano- or microstructure and the sample nano- or microstructure composing the test nano- or microstructure, and the measurement must be adapted accordingly. In one embodiment of the invention, the connection point of the test nano- or microstructure, the end point of the free reference nano- or microstructure, and the end point of the free sample nano- or microstructure are instrumented with displacement measurement tools such as cursors (13) or (14) (see FIG. 5A and FIG. 5B). In another embodiment of the invention, the cursors are more complex structures (16) or (15) in which a periodical structure is used to increase the accuracy on the displacement measurement (details about this optical extraction technique is given in P. Sandoz, J. Ravassard, S. Dembelé, and A. Janex, “Phase sensitive vision technique for high accuracy position measurement of moving targets”, IEEE Trans. Instrum. Meas. 49, 867-872 (2000)) (see FIG. 6A and FIG. 6B). In another embodiment of the invention, the cursors are replaced by one or more piezoresistive elements (17) located at the anchors (1) of the test nano- or microstructures (under the strain at the anchor the resistance of the piezoresistive material loop, usually polysilicon, changes and then displacements can be recorded by determining this resistance R change; similar piezoresistive material loops may be placed at the anchor of the free sample structure and/or the free reference structure to obtain a reference resistance value), see FIG. 7, or one or more capacitive nano- or microstructures as shown in FIG. 8. In that last case, the nano- or microstructure displacement is sensed by the capacitive coupling change between two electrodes (18), one moving with the nano- or microstructure and the other one fixed to anchors (9). The movement direction of the release electrode could be perpendicular (FIG. 8 (b), change of capacitance value by changing the spacing between electrodes) or parallel (FIG. 8 (d), change of capacitance value by changing the coupling area between the electrodes (18)) to the fixed electrode. Fully automated procedures can easily be implemented owing to the possibility to integrate the micro- or nano-machine of the invention together with the electronics on the same chip, which is the basic idea of a MEMS.

In another embodiment, the sample and reference structure are coupled by an intermediate structure equipped with one or more means for deriving directly or indirectly the dimensional information, such as, but not limited to, cursors, periodical structures, piezo-resistive elements or capacitive elements.

In another embodiment with the strain ε_{sub} applied only to the test micro- or nanostructure and substrate undeformed, the various displacements are measured relative to a point placed on the substrate near the connecting point between the sample microstructure and the reference microstructure.

The total strain is made of all the contributions to the change of length of the sample. In the case where the strain is only made of an internal strain (e.g. due to a mismatch between the coefficient of thermal expansion of the substrate and the sample nano- or microstructure) and a mechanical strain, the mechanical strain can be obtained as the difference between the total strain and internal strain.

The person skilled in the art can use the force equilibrium equation, the stiffness of the reference structure, the geometry and dimensions of the various structures, and the measurement of strain and/or change in dimensions to determine the overall mechanical strain ε₂^{mech} and stress σ₂ on the sample nano- or microstructure.

For the purpose of illustration, and without being bound by theory, the overall mechanical strain ε₂^{mech} and stress σ₂ imposed to the sample nano- or microstructure can be directly inferred in one embodiment illustrated in FIG. 1B from the measured displacements using the following set of equations:

$${ɛ}_{2}^{mech} = ln ( exp ( {ɛ}_{sub} ) + \frac{Δ {u}_{4 AL}}{{L}_{02}} ) - {ɛ}_{2 mis}$$

$${σ}_{2} = \frac{{S}_{ref}}{{S}_{2}} {E}_{ref} ( ln ( exp ( {ɛ}_{sub} ) - \frac{Δ {u}_{4 AL}}{{L}_{01}} ) - {ɛ}_{1 mis} )$$

where:
L₀₁ is the initial length (before release) of the reference nano- or microstructure;
L₀₂ is the initial length (before release) of the sample nano- or microstructure. This length can be smaller than the total length of the sample if a section reduction is used to avoid perturbation effects at the sample ends (FIG. 9 shows the so-called “Idog bone” geometry to be used for uniaxial tension with the definition of the length L₀₂);
Δu_{4AL} is positive if the test sample elongates
S_{ref} is the cross-section area of the reference sample;
S₂ is the cross-section area of the sample nano- or microstructure.
It was assumed that the reference material behaves as a linear elastic material characterized by Young's modulus E_{ref}.
It was assumed that there is no other contribution to the total strain than the mechanical strain and internal strain. When other contributions are present, such as a piezoelectric strain for instance, then it should also be introduced in the equations such as for the internal strain.

As a first good approximation the cross-section area of the sample nano- or microstructure S_{S} can be taken equal to the initial cross-section area S_{S0}. The quality of this approximation deteriorates if the strains in the sample nano- or microstructure become typically larger than 5%. Then, it is better to correct the value by using the following formula:

$${S}_{2} = \frac{{S}_{S 0}}{exp ( {ɛ}_{2}^{mech} )}$$

which is based on the assumption of volume conservation. The error on the section with this formula will usually be smaller than 1% except if strong volume changes (several percents) occur during the deformation which rarely occurs in materials. More accurate corrections can be used to take into account the change of cross-section related to the elasticity (usually very small) or volume compressibility.

The same correction can be made to the cross-section area of the reference sample, in which, usually the strains will remain much smaller than in the test sample.

The length of the reference nano- or microstructure (e.g. a beam) is preferably large enough to act as a deformation amplifier when either the maximum applied strain ε_{sub} is limited, for instance because of the brittleness of the substrate, or because the maximum that can be imposed to the reference micro- or nanostructure is limited, for instance because of its brittleness. The length of the reference nano- or microstructure in the test nano- or microstructure is preferably at least twice the length of the sample nano- or microstructure in the test nano- or microstructure and can be 100 times the length of the sample or even more. In terms of absolute length, a precise measurement requires to have a sample micro or nanostructure long enough for the first displacement Δu_{4AL} to be large enough for the resolution of the measurement technique. A valid measurement requires to have a good accuracy in the measurement of ε_{sub}, preferably better than 10%, and more preferably better than 3%. If ε_{sub} is derived from the measurement of Δu_{3AL} (see eqn. (3)), the total length L₀₁ is preferably long enough for the first displacement Δu_{3AL} to be large enough for the resolution of the measurement technique. The sample nano- or microstructure is preferably not too stiff for the displacement Δu_{4AL} to be large enough for the resolution of the measurement technique. The sample nano- or microstructure is preferably not too compliant for the displacement Δu_{4AL} to be not close to the free reference sample response. Typically, the sample structure has preferably a stiffness between 10 and 90% of the reference structure stiffness, preferably between 20 and 80%. The fabrication of many test nano- or microstructure with different dimensions (different absolute length and ratio of cross-section area) on a single substrate allows using the same design for different choice of material samples and material sample thicknesses. In this way, it increases the likelihood that there will be a sub-set of test nano- or microstructure respecting the design criterion.

The data reduction presented above is preferably used with thick substrate such that the presence of the films on the surface does not induce significant deformation of the substrate (i.e. less than 0.01%).

Single phase materials with minimum elastic anisotropy such as W and Al are preferred for the reference material in order to have well controlled E_{ref}. The reference material preferably has, for a plastically deforming material, a large yield stress to avoid early plastic deformation and a large fracture stress. The data reduction scheme can be adapted to the unusual case of reference samples becoming plastic. This requires knowing the plastic response of the reference material either by prior measurements (with the present technique or any other technique), or, in the case of the embodiment of the invention where the reference material and test material are the same, this requires using the measurements made during the same test at a earlier stage of applied deformation.

In some cases, large stress gradients may be present inside the test nano- or microstructure. In that case, the test nano- or microstructure will move out of plane and lead to difficulties for precisely determining the relevant displacements. Correction procedures well known to the person skilled in the art can be established if the effect is limited. Note that this problem also occurs in regular macroscopic tests on plate involving residual stress gradients.

In the case of non-homogeneous loading conditions, different sort of displacement measurements can be performed depending on the geometry. For instance, opening of notches, change of dimension of holes, crack (20) opening displacement can be used among others. Digital image correlation can also be employed to determine full strain fields. Alternatively, approximate solution or numerical simulations can be used to extract the local stress and/or strain values.

When the geometry contains holes (19) (see FIG. 11), crack (20) (see FIG. 12), notches (18) (see FIG. 10), the strain field is not homogeneous and numerical simulations are needed to extract local strain fields from the overall deformation applied to the sample nano- or microstructure.

In one embodiment: the sample nano- or microstructure can be strained up to failure by changing the imposed deformation ε_{sub}. It allows generating stress strain curves up to failure for homogeneous loading conditions and producing the stress strain field evolution up to failure for non homogeneous loading conditions for each test nano- or microstructure. The tests can be performed with interruptions, allowing, after each strain increment, the measurements of the displacements. Alternatively, the tests can be performed in a continuous way, which requires continuous electrical type measurements of the displacement. In that case, the loading rate applied to the substrate can be varied in order to address the effect of the strain rate sensitivity and cyclic loading can be applied to look at fatigue properties. In another embodiment, only a single extra external displacement is applied to the substrate and with several elementary machines differing by the length of the reference and/or of the sample nano- or microstructure, different strains will be applied to each sample nano- or microstructure which allows generating stress strain curves up to failure for homogeneous loading conditions and producing the stress strain field evolution up to failure for non homogeneous loading conditions for each test nano- or microstructure.

Starting from the above-stated principles, several types of micro- and nano-machines according to this invention can be made in view of different types of mechanical and/or electromechanical properties measurements. All these micro- and nano-machines can rely on one or more of the release methods explained above combined with one or more direct or indirect displacement or strain measurement techniques combined to one or more methods for applying the external stress optionally combined with one or more methods for applying physical conditions (stimulus) optionally combined with one or more methods for determining a physical state or property. All combinations are in principle possible. Without implying any limitation in the micro- and nano-machines that can be made according to this invention, each of the following embodiments for the type of properties to be measured will now be detailed by reference to FIGS. 9 to 16 respectively.

FIGS. 9 to 12 show a top view of the construction principle of a pulling micro- or nano-machine according to an embodiment of the present invention. FIG. 9 shows a so-called “dog-bone” geometry for uniaxial tension testing, avoiding the risk of failure at the connection region. Different amount of reduction of the sample can be imposed. The relevant sample nano- or microstructure length L₀₂ used in the calculations should be adapted as illustrated in the figure. FIG. 10 shows a notched sample nano- or microstructure for tension test. This is a case of non homogeneous deformation field. Other designs with multiple notches and other notches sizes can be made. FIG. 11 shows a sample nano- or microstructure sample with a hole (19). This is a case of non homogeneous deformation field. Other designs involving multiple holes, with various sizes, geometries and arrangements can be made. FIG. 12 shows a cracked sample nano- or microstructure sample for tension test. This is a case of non homogenous deformation field. Other designs with multiple cracks or with an inclined crack can be made.

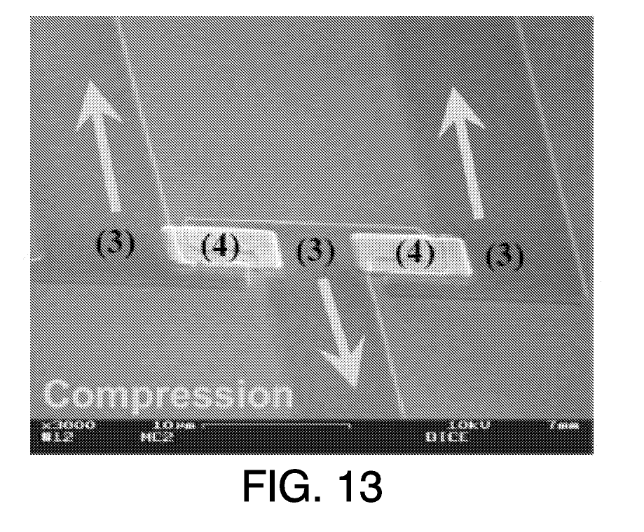

FIG. 13 shows a top view of the principle of a compression micro- or nano-machine according to an embodiment of the present invention, wherein (4) designates the sample nano- or microstructures. The reference nano- or microstructures are labelled with number (3).

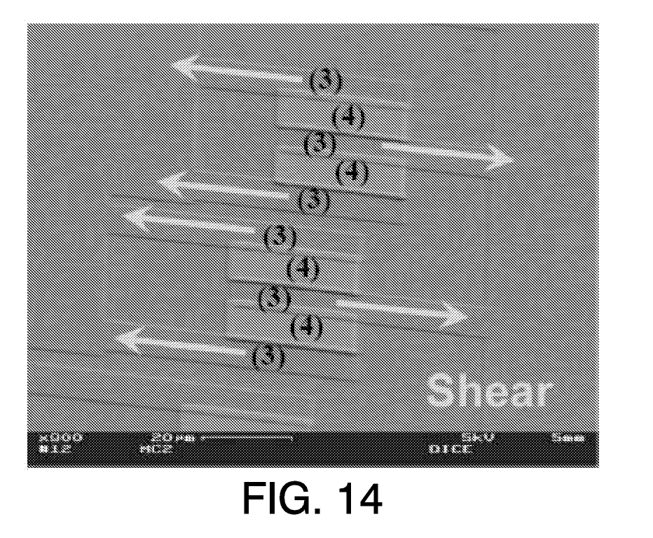

FIG. 14 shows a top view of the principle of a shearing micro- or nano-machine according to an embodiment of the present invention. Two sample nano- or microstructures (4) are schematised sandwiched between three reference nano- or microstructures (3). The nano- or microstructure is thus symmetric, making easier the data reduction.

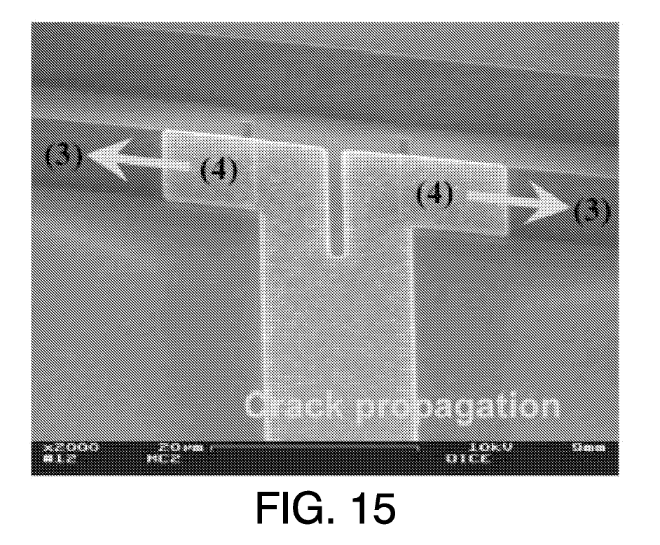

FIG. 15 shows a top view of the construction principle of a so-called Double Cantilever Beam micro- or nano-machine according to an embodiment of the present invention.

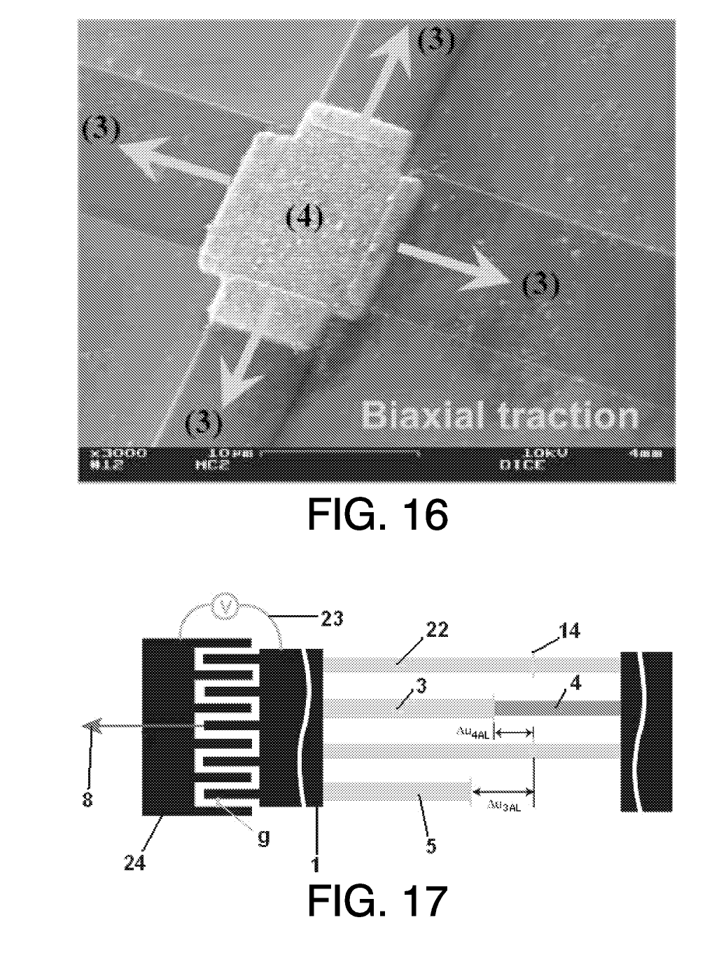

FIG. 16 shows a top view of the construction principle of a so-called biaxial test micro- or nano-machine according to an embodiment of the present invention. In this specific case, the displacement to the test nano- or microstructure must be imposed in two different directions.

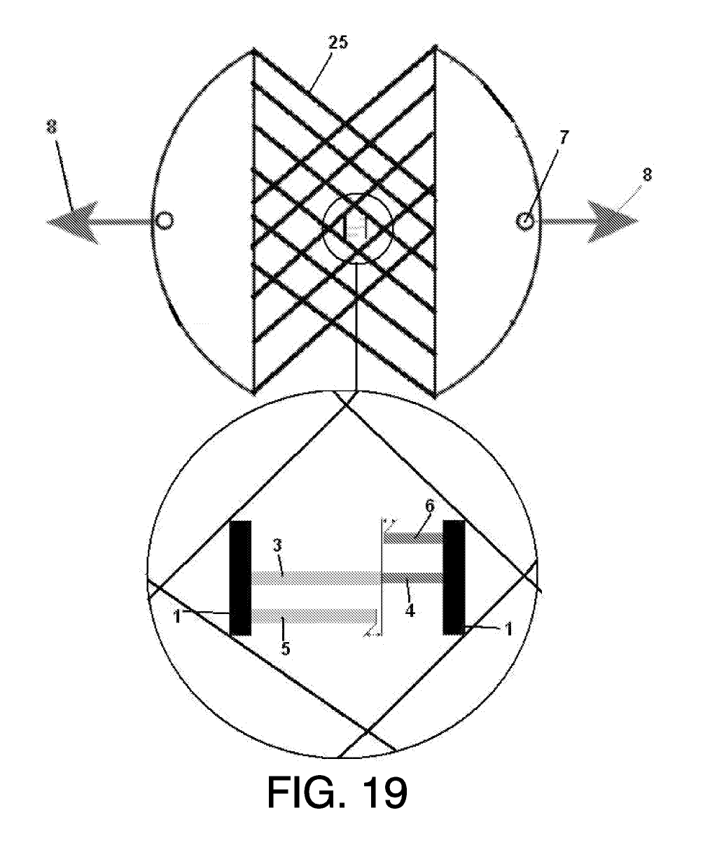

FIG. 19 shows a device according to a particular embodiment of the present invention wherein the external mechanical force and/or the displacement it generates is scaled down via a lattice or mesh structure (25). This makes it easier to apply the force. This is also a method to allow imposing more strain to a brittle substrate, while also avoiding the need to use too long reference beam to de-multiply the deformation.

As stated herein-above, one optional feature of this invention is a step providing release of the test nano- or microstructures, i.e. release of the reference and the sample nano- or microstructures. Once all the deposits and the lithographic steps have been performed, the whole structure is released. In an embodiment, the release of the structure is operated by erasing the sacrificial layer placed below the beams. In another embodiment, it is a portion of the substrate itself which is erased in order to release the structure. This release may be performed simultaneously with the etching of the material to be stressed. If the beams are deposited directly on the substrate, the whole structure is released by etching the portion of the substrate below the beams. Appropriate etching means that the etching substance is selected according to its selectivity with respect to the material to be stressed. Appropriate selection of the etching substance is within the general knowledge of the person skilled in the art. For instance, it is known that concentrated fluorhydric acid does not etch aluminium, TMAH solution etches undoped Si or polysilicon without attacking silicon dioxide or silicon nitride, SF6 plasma etches Si without attacking polymer, polymer dissolved in solvents without damaging most of the material used in microelectronics, etc. The removal of the sacrificial portion of the substrate by etching may be facilitated by the local doping or implantation of elements in the substrate.

By releasing the structure in this way, the reference nano- or microstructure and the sample nano- or microstructure are no longer resting on anything. If necessary under certain circumstances, i.e. for certain combinations of materials, the bonding effect which may be observed between the substrate and the released structure may be avoided by means of supercritical drying of the sample, e.g. making use of a so-called “critical point dryer”.

Thanks to the conceptual simplicity of the micro- and nano-machines of this invention, their manufacturing process is straightforward and reliable. In its simplest version, the full micro-fabrication process requires only three film depositions and two photolithographic steps in order to build a nano- or microstructure that can be operated for precise measurements of mechanical properties.

In view of its simplicity and effectiveness, the present invention is widely applicable to a large range of sample nano- or microstructure, each of them being in a wide range of thicknesses, widths and geometries.

Thin and ultra-thin film materials that can be used as sample for the performance of the invention include, but are not limited to:

metals and metal alloys such as, but not limited to, aluminum, palladium, steel, stainless steel, titanium, nickel, and the like,

silicon-based materials such as, but not limited to, various grades of silicon chips, silicon carbide, and the like,

germanium based materials,

carbon-based materials such as, but not limited to, carbon nano-tubes, carbon nano-wires, carbides and the like, and

polymer based materials, in particular conductive polymers such as, but not limited to, polyaniline, polypyrolle, polyethylene terephthalate/polyaniline composites, and acid-doped versions thereof.

Multilayers made of the above cited layers

The present invention is widely applicable to mono-layer thin and ultra-thin films as well as multi-layer films, whatever the number of layers in their structure and the thickness of each layer. The range of thickness for the thin or ultra-thin layer film to be stressed according to the method and device of the invention preferably ranges from about 1 nm to about 10 μm, more preferably from about 5 nm to about 2 μm, and most preferably from about 50 nm to about 1 μm.

The concept of this invention is thus not necessarily focused onto one complex machine but relates in some embodiments to using multiple elementary test nano- or microstructures on a single substrate to generate a complete laboratory. This allows, with one large set of nano- or microstructures, the generation of valid results (there will often be nano- or microstructures in the valid design range), of statistically representative data, of results associated to different geometries and loading conditions.

1-28. (canceled)

29. A device for characterizing one or more sample nano- or micro-structures (4), said device comprising:
a substrate (1) optionally comprising a sacrificial portion or layer (2), and
one or more reference (3) nano- or microstructures directly or indirectly attachable to one or more sample nano- or microstructures (4) to form one or more test nano- or microstructures, wherein said one or more reference nano- or microstructure (3) is directly or indirectly attached to said substrate (1) in such a way that a part of said one or more reference (3) nano- or microstructure stands free or would stand free if said optional sacrificial portion or layer (2) was removed, said one or more test nano- or microstructures being adapted for being subjected to an external mechanical load directly or indirectly imposed, in such a way that the resulting stress and/or strain in the one or more reference nano-microstructure is essentially uniformly compressive or tensile, wherein the length of the reference nano- or microstructure is at least twice the length of the sample nano- or microstructure.

30. A system for imposing and determining the stress and/or strain imposed to at least one sample nano- or micro-structures (4), the system comprising:
a device comprising a substrate (1) optionally comprising a sacrificial portion or layer (2), and one or more reference nano- or microstructures (3) directly or indirectly attachable to one or more sample nano- or microstructures (4) to form one or more test nano- or microstructures, wherein said one or more reference nano- or microstructure (3) is directly or indirectly attached to said substrate (1) in such a way that a part of said one or more reference nano- or microstructure (3) can stands free or would stand free if said optional sacrificial portion or layer (2) was removed, said one or more test nano- or microstructures being adapted for being subjected to an external mechanical load directly or indirectly imposed, in such a way that the resulting stress and/or strain in the one or more reference nano-microstructure is essentially uniformly compressive or tensile, and
means (7, 8) for directly or indirectly imposing an external mechanical load on said one or more test nano- or microstructures or on said substrate in such a way that the stress and/or strain in said reference nano- or microstructure is essentially uniformly compressive or tensile, wherein the length of the reference nano- or microstructure is at least twice the length of the sample nano- or microstructure.

31. The system according to claim 30, the system further comprising a means for directly or indirectly providing dimensional and/or strain information on said sample and/or reference and/or test nano- or microstructure based on a response to said imposed external mechanical load on said test nano- or microstructure.

32. The system according to claim 30, wherein said means for imposing an external mechanical load (7, 8, 10) can reversibly impose said imposed external mechanical load on said test nano- or microstructure and/or wherein said means (7, 8, 10) for imposing an external mechanical load on said test nano- or microstructures are magnetic, mechanic, electrostatic, electromagnetic, optical, acoustic, thermal, chemical, structural, nuclear or quantum means, or a combination thereof.

33. The system according to claim 30, wherein the substrate comprises a mesh structure (25) and/or wherein said substrate comprises a sacrificial portion or layer (2) and wherein said nano- or microstructures can be made free upon removal of the sacrificial portion or layer (2).

34. The system according to claim 30, said system further comprising one or more means to apply one or more stimulus on the sample nano- or microstructure and/or to measure one or more states or properties of the sample nano- or microstructure selected from the list consisting of mechanical, electrical, optical, chemical, acoustical, thermal, structural, nuclear and quantum mechanical stimulus, state and/or properties.

35. The system according to claim 31, wherein said means for directly or indirectly providing dimensional and/or strain information comprises:
one or more free sample nano- or microstructures (6) separate from any reference nano- or microstructures (3, 5), and/or
one or more free reference nano- or microstructures (5) separate from any sample nano- or microstructures (4, 6) and/or
one or more double clamped beam, and/or
wherein said means for directly or indirectly providing dimensional and/or strain information comprise cursors (13, 14, 15, 16); and/or
wherein said means for directly or indirectly providing dimensional and/or strain information comprise piezo resistive elements (17); and/or
wherein said means for directly or indirectly providing dimensional and/or strain information comprises at least two electrodes (18), one moving with the test nano- or microstructures and the other one fixed directly or indirectly to a free nano- or microstructure or to the substrate (9).

36. The system according to claim 30, wherein the sample nano- or microstructures (4) comprise a section reduction and/or one or more notches (18) and/or one or more holes (19) and/or one or more cracks (20).

37. The system according to claim 30, wherein the device comprises at least two reference nano- or microstructures (3) attached to a sample nano- or microstructure (4) and arranged to test said sample nano- or microstructure (4) in traction, shear, compression, crack propagation or biaxial traction measurement.

38. The system according to claim 30, wherein said system furthermore comprises a processor for deriving one or more physical state or properties of said sample nano- or microstructures from said dimensional and/or strain information and/or from the measurement of state and/or properties of the sample nano- or microstructures selected from the list consisting of mechanical, electrical, optical, chemical, acoustical, thermal, structural, nuclear and quantum mechanical state and properties.

39. The system according to claim 31, said system further comprising a controller for adapting said stress imposed externally on the one or more test nano- or microstructure as a function of said dimensional and/or strain information and/or of the measurement of state and/or properties of the one or more sample nano- or microstructures selected from the list consisting of mechanical, electrical, optical, chemical, acoustical, thermal, structural, nuclear and quantum mechanical state and properties.

40. A method for assisting in characterizing a sample nano- or micro-structures (4), the method comprising
directly or indirectly imposing an external mechanical load on one or more test nano- or microstructure comprising one or more reference nano- or microstructure (3) directly or indirectly attached to one or more sample nano- or microstructure (4), wherein the one or more reference nano- or microstructures (3) is directly or indirectly attached to a substrate so as to stand free with respect to the substrate, said external mechanical load being imposed in such a way that induced stress and/or strain in the one or more reference nano- or microstructure is essentially uniformly compressive or tensile and the length of the reference nano- or microstructure is at least twice the length of the sample nano- or microstructure.

41. The method according to claim 40, the method comprising directly or indirectly providing dimensional and/or strain information on the one or more sample and/or reference and/or test nano- or microstructure based on a response to said imposed stress and/or strain on the test nano- or microstructure.

42. The method according to claim 40, wherein the method furthermore comprises
applying one or more chemical, optical, thermal, electrical, chemical, acoustical, structural, nuclear or quantum mechanical stimulus on the sample nano- and microstructure, and/or
determining one or more chemical, optical, thermal, electrical, chemical, acoustical, structural, nuclear or quantum mechanical state or property on the one or more sample nano- or microstructures.

43. The method according to claim 42, the method furthermore comprising deriving one or more physical or multi-physics property from said dimensional and/or stress information and/or from the one or more chemical, optical, thermal electrical, chemical, acoustical, structural, nuclear or quantum mechanical state or property measured on the one or more sample nano- or microstructure.

44. The method according to claim 40, wherein the method further comprises, prior to said imposing externally stress and/or strain, removing a sacrificial layer on the substrate and/or sacrificial portion of the substrate wherein said one or more sample and/or reference nano- or microstructures are positioned so as to obtain one or more free-standing sample and/or reference nano- or microstructures.

45. The method according to claim 40, wherein the method furthermore comprises controlling said stress and/or strain imposed on said test nano- or microstructure as a function of said dimensional and/or strain information and/or of said measurement of state and/or properties of the sample nano- or microstructures selected from the list consisting of mechanical, electrical, optical, chemical, acoustical, thermal, structural, nuclear and quantum mechanical state and properties.

46. A method for manufacturing a system for imposing and determining stress and/or strain to sample nano- or microstructures, the method for manufacturing comprising
forming a device by obtaining a substrate (1) and attaching directly or indirectly one or more reference (3) nano- or microstructures to said substrate (1) so that a part of said one or more reference nano- or microstructure (3) can stand free, said one or more reference (3) nano- or microstructures being directly or indirectly attachable to said one or more sample nano- or microstructure (4) to form one or more test nano- or microstructure,
providing one or more means (7, 8, 10) for directly or indirectly imposing an external mechanical load on said one or more test nano- or microstructure in such a way that the stress and/or strain induced in the reference nano- or microstructure is essentially uniformly compressive or tensile,
wherein the length of the reference nano- or microstructure is at least twice the length of the sample nano- or microstructure.

47. The method according to claim 46, the method comprising providing means for directly or indirectly providing dimensional and/or strain information on said sample and/or reference and/or test nano- or microstructure based on a response to said imposed external mechanical load on said one or more test nano- or microstructure.
